(19) United States
(12) Patent Application Publication
(10) Pub. No.: US 2024/0298442 A1
(43) Pub. Date: Sep. 5, 2024

(54) MEMORY DEVICE AND METHOD OF FABRICATING THE SAME

(71) Applicant: MACRONIX International Co., Ltd., Hsinchu (TW)

(72) Inventor: Yan-Ru Su, Chiayi County (TW)

(73) Assignee: MACRONIX International Co., Ltd., Hsinchu (TW)

(21) Appl. No.: 18/177,138

(22) Filed: Mar. 2, 2023

(51) Int. Cl. H10B 43/27

(52) U.S. Cl. CPC H10B 43/27

(57) ABSTRACT

A memory device includes a substrate, a stacked structure, a separation wall, first and second through vias. The substrate includes a memory array region and a staircase region. The stacked structure is located on the substrate in the memory array region and the staircase region. The stacked structure includes conductive layers and insulating layers stacked alternately. The separation wall extends through the stacked structure and divides the stacked structure into first and second blocks. The first through vias are in the first block of the staircase region. The second through vias are in the second block of the staircase region and adjacent to the first through vias. The number of layers of the stacked structure penetrated by the first through vias is smaller than the number of layers of the stacked structure penetrated by the second through vias. The memory device may be applied in a 3D AND flash memory.

### BACKGROUND

### Technical Field

The embodiments of the present disclosure relate to a semiconductor device and a method of fabricating the same, and particularly to a memory device and a method of fabricating the same.

### Description of Related Art

Since a non-volatile memory has the advantage that stored data does not disappear at power-off, it becomes a widely used memory for a personal computer or other electronics equipment. Currently, the three-dimensional (3D) memory commonly used in the industry includes a NOR memory and a NAND memory. In addition, another type of 3D memory is an AND memory, which may be applied to a multi-dimensional memory array with high integration and high area utilization, and has an advantage of a fast operation speed. Therefore, the development of a 3D memory device has gradually become the current trend. However, there are still many challenges associated with the 3D memory device.

### SUMMARY

The embodiments of the present disclosure provide a memory device and a fabricating method thereof, in which the difficulty of the process can be reduced, conductive vias electrically isolated from the interconnection structure can be prevented, and the yield of the process can be improved.

In an embodiment of the present disclosure, a memory device includes a substrate, a stacked structure, a separation wall, multiple first through vias, and multiple second through vias. The substrate includes a memory array region and a staircase region. The stacked structure is located on the substrate in the memory array region and the staircase region, wherein the stacked structure includes a plurality of conductive layers and a plurality of insulating layers stacked alternately. The separation wall extend through the stacked structure to divide the stacked structure into a first block and a second block. The first through vias are located in the first block of the staircase region. The second through vias are located in the second block of the staircase region and adjacent to the first through vias. A number of layers of the stacked structure penetrated by the first through vias is smaller than a number of layers of the stacked structure penetrated by the second through vias.

In an embodiment of the present disclosure, a memory device includes a substrate, a memory array, a staircase structure and first through vias. The substrate includes a memory array region and a staircase region. The memory array is located in the memory array region. The staircase structure is located on the substrate in the staircase region, wherein the staircase structure includes a recess region and a non-recess region, and a height of a top surface of the recess region is lower than a height of a top surface of the non-recess region. The first through vias are located in the recess region.

In an embodiment of the present disclosure, a method of fabricating a memory device includes the following steps. A substrate is provided. The substrate includes a memory array region and a staircase region. A stacked structure is formed in the memory array region and the staircase region. The stacked structure in the staircase region is patterned to form a staircase structure. A part of the staircase structure is partially removed to form a recess. A memory array is formed in the memory array region. First through vias are formed in the recess.

In view of the above, in the memory device and its fabricating method according to the embodiments of the present disclosure, the “open” issue that excessively inclined sidewall of the conductive via opening results in excessive insulating layer remaining at the bottom of the conductive via opening and therefore causes insufficient etching unable to reach the topmost conductive layer of the interconnection structure can be avoided. Therefore, the difficulty of the process can be reduced and the yield of the process can be improved by the method of the embodiments of the present disclosure.

### BRIEF DESCRIPTION OF THE DRAWINGS

FIG. 1A is a circuit diagram of a 3D AND flash memory array according to some embodiments.

FIG. 1B is a partial perspective view of a part of the memory array in FIG. 1A.

FIG. 1C and FIG. 1D are cross-sectional views taken along the line I-I′ of FIG. 1B.

FIG. 1E is a top view of the line II-II′ of FIG. 1B, FIG. 1C, FIG. 1D.

FIG. 2A is a top view of a memory die, according to an embodiment of the disclosure.

FIG. 2B is a top view of a partial area of FIG. 2A.

FIG. 3A is a top view of a memory device according to an embodiment of the present disclosure.

FIG. 3B is a perspective view of a partial area of FIG. 3A.

FIG. 3C is a cross-sectional view taken along the line A-A′ of FIG. 3B.

FIG. 4A is a top view of a memory device according to another embodiment of the present disclosure.

FIG. 4B is a perspective view of a partial area of FIG. 4A.

FIG. 4C is a cross-sectional view taken along the line B-B′ of FIG. 4B.

FIG. 4D is a cross-sectional view taken along the line C-C′ or D-D′ of FIG. 4B.

FIG. 5A is a top view of a memory device according to yet another embodiment of the present disclosure.

FIG. 5B is a cross-sectional view taken along the line E-E′ of FIG. 5A.

FIG. 5C is a top view of a memory device according to yet another embodiment of the present disclosure.

FIG. 5D is a cross-sectional view taken along the line F-F′ of FIG. 5C.

FIG. 6A to FIG. 6E are schematic cross-sectional views of a method of fabricating the memory device of FIG. 3A.

FIG. 7A to FIG. 7E are perspective views of partial areas in FIG. 6A to FIG. 6E.

FIG. 8A to FIG. 8D are cross-sectional views of a method of fabricating the memory device of FIG. 4A.

FIG. 9A to FIG. 9D are perspective views of partial areas in FIG. 8A to FIG. 8D.

FIG. 10A to FIG. 10C are schematic cross-sectional views of various separation structures according to embodiments of the present disclosure.

FIG. 11A is a top view of a memory die according to another embodiment of the present disclosure.

FIG. 11B is a top view of a partial area of FIG. 11A.

### DESCRIPTION OF THE EMBODIMENTS

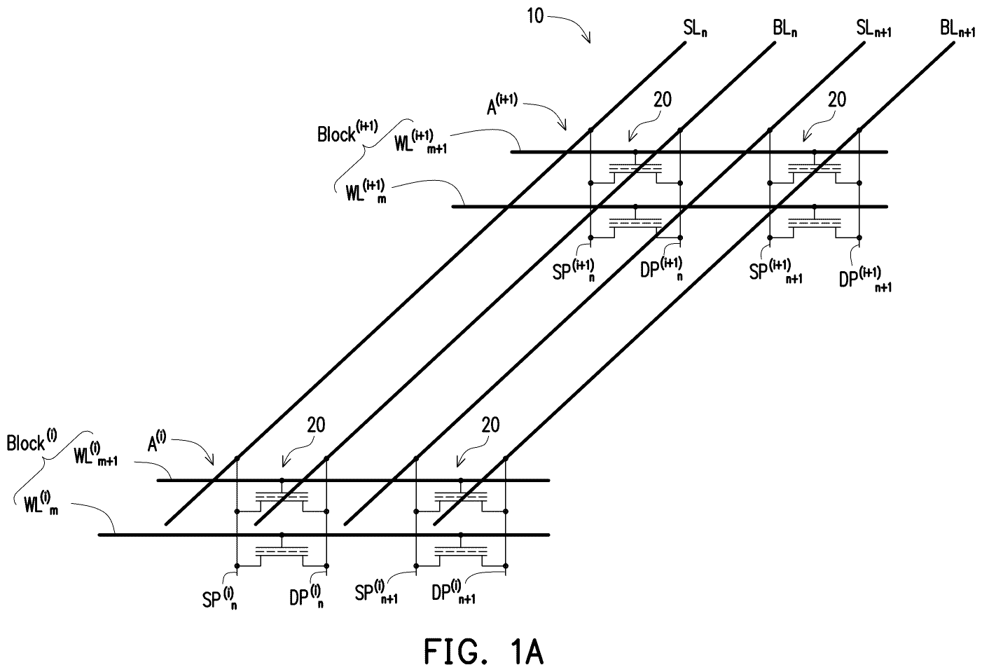

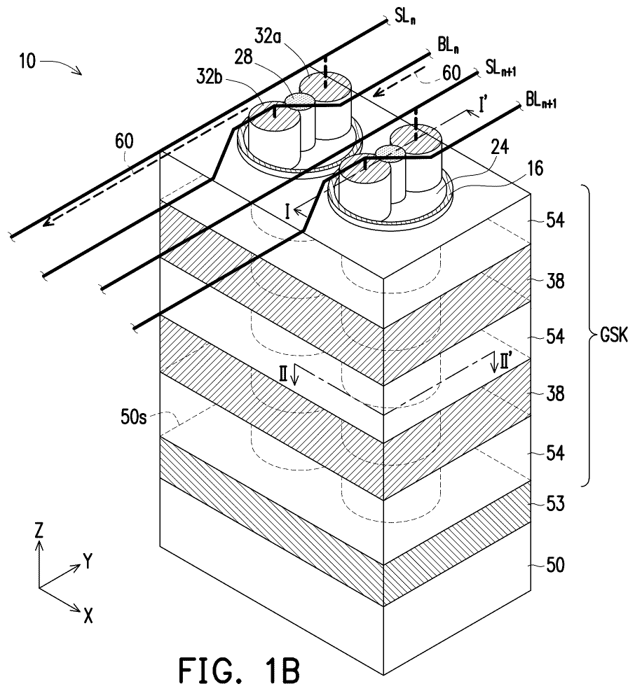

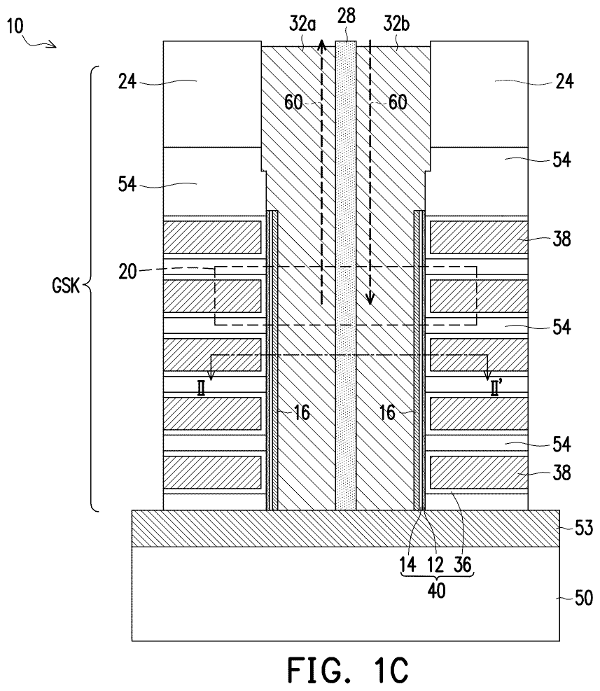

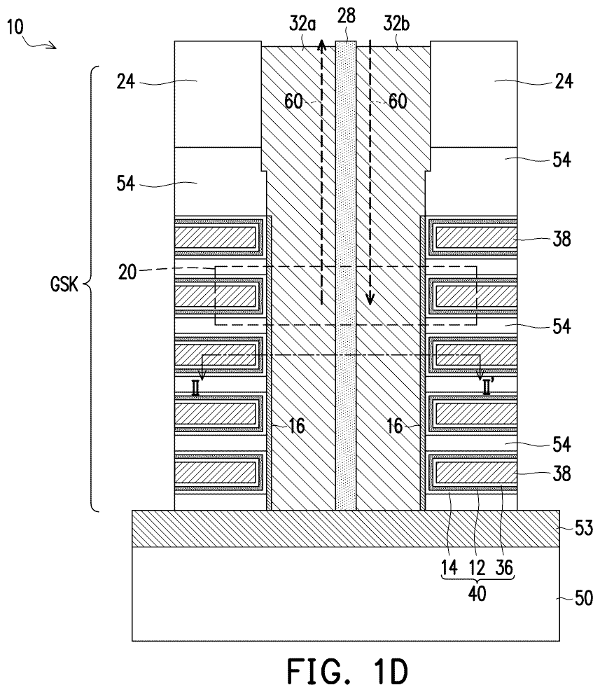

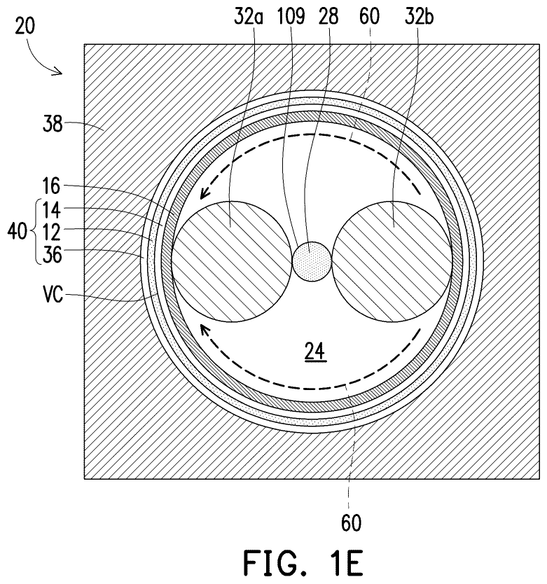

FIG. 1A is a circuit diagram of a 3D AND flash memory array according to some embodiments. FIG. 1B is a partial perspective view of a part of the memory array in FIG. 1A. FIG. 1C and FIG. 1D are cross-sectional views taken along line I-I′ of FIG. 1B. FIG. 1E is a top view of line II-II′ of FIG. 1B, FIG. 1C, and FIG. 1D.

FIG. 1A is a schematic view of two blocks BLOCK⁽ⁱ⁾ and BLOCK⁽ⁱ⁺¹⁾ of a vertical AND memory array 10 arranged in rows and columns. The block BLOCK⁽ⁱ⁾ includes a memory array A⁽ⁱ⁾. A row (e.g., an (m+1)^{th} row) of the memory array A⁽ⁱ⁾ is a set of AND memory cells 20 having a common word line (e.g., WL⁽ⁱ⁾ₘ₊₁). The AND memory cells 20 of the memory array A⁽ⁱ⁾ in each row (e.g., the (m+1)^{th} row) correspond to a common word line (e.g., WL⁽ⁱ⁾ₘ₊₁) and are coupled to different source pillars (e.g., SP⁽ⁱ⁾ₙ and SP⁽ⁱ⁾ₙ₊₁) and drain pillars (e.g., DP⁽ⁱ⁾ₙ and DP⁽ⁱ⁾ₙ₊₁), so that the AND memory cells 20 are logically arranged in a row along the common word line (e.g., WL⁽ⁱ⁾ₘ₊₁).

A column (e.g., an n^{th} column) of the memory array A⁽ⁱ⁾ is a set of AND memory cells 20 having a common source pillar (e.g., SP⁽ⁱ⁾ₙ) and a common drain pillar (e.g., DP⁽ⁱ⁾ₙ). The AND memory cells 20 of the memory array A⁽ⁱ⁾ in each column (e.g., the n^{th} column) correspond to different word lines (e.g., WL⁽ⁱ⁾ₘ₊₁ and WL⁽ⁱ⁾ₘ) and are coupled to a common source pillar (e.g., SP⁽ⁱ⁾ₙ) and a common drain pillar (e.g., DP⁽ⁱ⁾ₙ). Hence, the AND memory cells 20 of the memory array A⁽ⁱ⁾ are logically arranged in a column along the common source pillar (e.g., SP⁽ⁱ⁾ₙ) and the common drain pillar (e.g., DP⁽ⁱ⁾ₙ). In the physical layout, according to the fabrication method as applied, the columns or rows may be twisted and arranged in a honeycomb pattern or other patterns for high density or other reasons.

In FIG. 1A, in the block BLOCK⁽ⁱ⁾, the AND memory cells 20 in the n^{th} column of the memory array A⁽ⁱ⁾ share a common source pillar (e.g., SP⁽ⁱ⁾ₙ) and a common drain pillar (e.g., DP⁽ⁱ⁾ₙ). The AND memory cells 20 in an (n+1)^{th} column share a common source pillar (e.g., SP⁽ⁱ⁾ₙ₊₁) and a common drain pillar (e.g., DP⁽ⁱ⁾ₙ₊₁).

The common source pillar (e.g., SP⁽ⁱ⁾ₙ) is coupled to a common source line (e.g., SLₙ) and the common drain pillar (e.g., DP⁽ⁱ⁾ₙ) is coupled to a common bit line (e.g., BLₙ). The common source pillar (e.g., SP⁽ⁱ⁾ₙ₊₁) is coupled to a common source line (e.g., SLₙ₊₁) and the common drain pillar (e.g., DP⁽ⁱ⁾ₙ₊₁) is coupled to a common bit line (e.g., BLₙ₊₁).

Likewise, the block BLOCK⁽ⁱ⁺¹⁾ includes a memory array A₍ᵢ₊₁₎, which is similar to the memory array A⁽ⁱ⁾ in the block BLOCK⁽ⁱ⁾. A row (e.g., an (m+1)^{th} row) of the memory array A⁽ⁱ⁺¹⁾ is a set of AND memory cells 20 having a common word line (e.g., WL⁽ⁱ⁺¹⁾ₘ₊₁). The AND memory cells 20 of the memory array A⁽ⁱ⁺¹⁾ in each row (e.g., the (m+1)^{th} row) correspond to a common word line (e.g., WL⁽ⁱ⁺¹⁾ₘ₊₁) and are coupled to different source pillars (e.g., SP⁽ⁱ⁺¹⁾ₙ and SP⁽ⁱ⁺¹⁾ₙ₊₁) and drain pillars (e.g., DP⁽ⁱ⁺¹⁾ₙ and DP⁽ⁱ⁺¹⁾ₙ₊₁). A column (e.g., an n^{th} column) of the memory array A⁽ⁱ⁺¹⁾ is a set of AND memory cells 20 having a common source pillar (e.g., SP⁽ⁱ⁺¹⁾ₙ) and a common drain pillar (e.g., DP⁽ⁱ⁺¹⁾ₙ). The AND memory cells 20 of the memory array A⁽ⁱ⁺¹⁾ in each column (e.g., the n^{th} column) correspond to different word lines (e.g., WL⁽ⁱ⁺¹⁾ₘ₊₁ and WL⁽ⁱ⁺¹⁾ₘ) and are coupled to a common source pillar (e.g., SP⁽ⁱ⁺¹⁾ₙ) and a common drain pillar (e.g., DP⁽ⁱ⁺¹⁾ₙ). Hence, the AND memory cells 20 of the memory array A⁽ⁱ⁺¹⁾ are logically arranged in a column along the common source pillar (e.g., SP⁽ⁱ⁺¹⁾ₙ) and the common drain pillar (e.g., DP⁽ⁱ⁺¹⁾ₙ).

The block BLOCK⁽ⁱ⁺¹⁾ and the block BLOCK⁽ⁱ⁾ share source lines (e.g., SLₙ and SLₙ₊₁) and bit lines (e.g., BLₙ and BL₁+). Therefore, the source line SLₙ and the bit line BLₙ are coupled to the n^{th} column of AND memory cells 20 in the AND memory array A⁽ⁱ⁾ of the block BLOCK⁽ⁱ⁾, and are coupled to the n^{th} column of AND memory cells 20 in the AND memory array A⁽ⁱ⁺¹⁾ of the block BLOCK⁽ⁱ⁺¹⁾. Similarly, the source line SLₙ₊₁ and the bit line BLₙ₊₁ are coupled to the (n+1)^{th} column of AND memory cells 20 in the AND memory array A⁽ⁱ⁾ of the block BLOCK⁽ⁱ⁾, and are coupled to the (n+1)^{th} column of AND memory cells 20 in the AND memory array A⁽ⁱ⁺¹⁾ of the block BLOCK⁽ⁱ⁺¹⁾.

Referring to FIG. 1B to FIG. 1D, the memory array 10 may be disposed over an interconnection structure of a semiconductor die, for example, being disposed on one or more active devices (e.g., transistors) formed on a semiconductor substrate. Therefore, a dielectric substrate (or called dielectric layer) 50 may be a dielectric layer (e.g., a silicon oxide layer) over a metal interconnection structure formed on a silicon substrate. The memory array 10 may include a stacked structure GSK, multiple channel pillars 16, multiple first conductive pillars (also referred to as source pillars) 32a, multiple second conductive pillars (also referred to as drain pillars) 32b, and multiple charge storage structures 40.

Referring to FIG. 1B, the stacked structure GSK is formed on the dielectric substrate 50. The stacked structure GSK includes multiple gate layers (also referred to as word lines or conductive layers) 38 and multiple insulating layer 54 vertically stacked on a surface 50s of the dielectric substrate 50. In a direction Z, the gate layers 38 are electrically isolated from each other by the insulating layer 54 disposed therebetween. The gate layers 38 extend in a direction parallel to the surface of the dielectric substrate 50. The gate layers 38 in the staircase region SR may have a staircase structure SC. Therefore, a lower gate layer 38 is longer than an upper gate layer 38, and the end of the lower gate layer 38 extends laterally beyond the end of the upper gate layer 38. Contacts (not shown) for connecting the gate layers 38 may be landed on the ends of the gate layers 38 to connect the gate layers 38 respectively to conductive lines.

Referring to FIG. 1B to FIG. 1D, the memory array 10 further includes multiple channel pillars 16. The channel pillars 16 extend continuously through the stacked structure GSK and to the conductive layer 53 between the dielectric substrate 50 and the stacked structure GSK. The material of the conductive layer 53 may include doped polysilicon. For example, the material of the conductive layer 53 may include P-type doped polysilicon. In some embodiments, each channel pillar 16 may have a ring shape from a top view. The material of the channel pillars 16 may include semiconductor, such as undoped polysilicon.

Referring to FIG. 1B to FIG. 1D, the memory array 10 further includes multiple insulating pillars 28, multiple first conductive pillars 32a, and multiple second conductive pillars 32b. In this example, the first conductive pillars 32a serve as source pillars. The second conductive pillars 32b serve as drain pillars. The first conductive pillars 32a, the second conductive pillars 32b, and the insulating pillars 28 each extend in a direction (i.e., the direction Z) perpendicular to the surface (i.e., the X-Y plane) of the gate layer 38. The first conductive pillar 32a and the second conductive pillar 32b are separated by the insulating pillar 28 and surrounded by an insulating filling layer 24. The first conductive pillar 32a and the second conductive pillar 32b are electrically connected to the channel pillar 16. The first conductive pillar 32a and the second conductive pillar 32b may include doped polysilicon or metal materials. The insulating pillar 28 may include silicon nitride or silicon oxide, and the insulating filling layer 24 may include silicon oxide.

Referring to FIG. 1C and FIG. 1D, a charge storage structure 40 is disposed between the channel pillar 16 and the gate layers (or called conductive layers) 38. The charge storage structure 40 may include a tunneling layer (or referred to as a bandgap engineered tunneling oxide layer) 14, a charge storage layer 12, and a blocking layer 36. The charge storage layer 12 is located between the tunneling layer 14 and the blocking layer 36. In some embodiments, the tunneling layer 14 and the blocking layer 36 include silicon oxide. The charge storage layer 12 includes silicon nitride or other materials capable of trapping charges. In some embodiments, as shown in FIG. 1C, a portion (e.g., the tunneling layer 14 and the charge storage layer 12) of the charge storage structure 40 continuously extends in a direction (i.e., the direction Z) perpendicular to the gate layer 38, and another portion (e.g., the blocking layer 36) of the charge storage structure 40 surrounds the gate layer 38. In other embodiments, as shown in FIG. 1D, the charge storage structure 40 (e.g., the tunneling layer 14, the charge storage layer 12, and the blocking layer 36) surrounds the gate layer 38.

Referring to FIG. 1E, the charge storage structure 40, the channel pillar 16, the source pillar 32a, and the drain pillar 32b are surrounded by the gate layer 38, and a memory cell 20 is accordingly defined. According to different operation methods, a 1-bit operation or a 2-bit operation may be performed on the memory cell 20. For example, when a voltage is applied to the source pillar 32a and the drain pillar 32b, since the source pillar 32a and the drain pillar 32b are connected to the channel pillar 16, electrons may be transferred along the channel pillar 16 and stored in the entire charge storage structure 40. Accordingly, a 1-bit operation may be performed on the memory cell 20. In addition, for an operation involving Fowler-Nordheim tunneling, electrons or holes may be trapped in the charge storage structure 40 between the source pillar 32a and the drain pillar 32b. For an operation involving source side injection, channel-hot-electron injection, or band-to-band tunneling hot carrier injection, electrons or holes may be locally trapped in the charge storage structure 40 adjacent to one of the source pillar 32a and the drain pillar 32b. Accordingly, a single level cell (SLC, 1 bit) or multi-level cell (MLC, greater than or equal to 2 bits) operation may be performed on the memory cell 20.

During operation, a voltage is applied to a selected word line (gate layer) 38; for example, when a voltage higher than a corresponding threshold voltage (Vₜₕ) of the corresponding memory cell 20 is applied, a channel region of the channel pillar 16 intersecting the selected word line 38 is turned on to allow a current to enter the drain pillar 32b from the bit line BLₙ or BLₙ₊₁ (shown in FIG. 1i), flow to the source pillar 32a via the turned-on channel region (e.g., in a direction indicated by arrow 60), and finally flow to the source line SLₙ or SLₙ₊₁ (shown in FIG. 1).

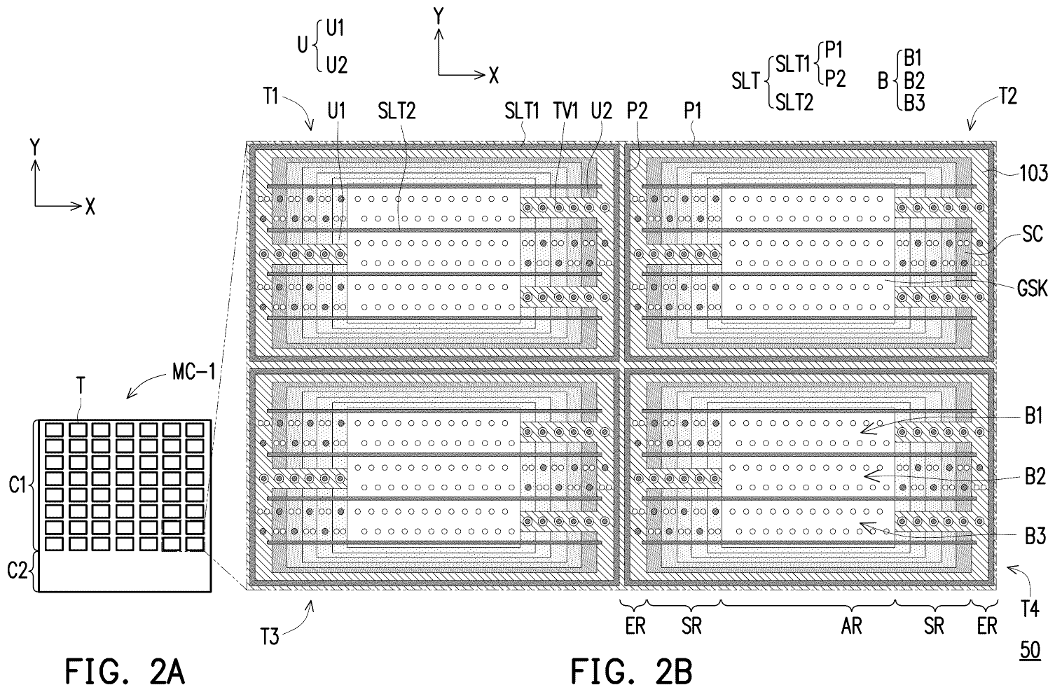

FIG. 2A is a top view of a memory die, according to an embodiment of the disclosure. FIG. 2B is a top view of a partial area of FIG. 2A.

Referring to FIG. 2A and FIG. 2B, a memory chip MC-1 may be an AND memory device. The memory chip MC-1 may include a region C1 and a region C2. The region C1 may include multiple tiles T separated from each other. The tiles T may be arranged in an array with multiple rows and multiple columns. In FIG. 2A, the tile array is formed by seven rows and eight columns, but the embodiment of the present disclosure is not limited thereto. Each tile T in the region C1 has multiple memory arrays. The region C2 includes peripheral circuits, such as complementary metal oxide semiconductor devices (CMOS), disposed on the periphery of the tilt array.

Still referring to FIG. 2A and FIG. 2B, the memory chip MC-1 further includes multiple sets of separation structures SLT. Each set of separation structures SLT includes a first separation wall SLT1 and multiple second separation walls SLT2. The separation wall is also called a slit or a partition wall in some examples.

The first separation wall SLT1 surrounds the periphery of the second separation walls SLT2, and the second separation walls SLT2 are formed inside the first separation wall SLT1. The first separation wall SLT1 may be circular from a top view. The second separation walls SLT2 are long strips extending in the X direction and arranged in the Y direction. In some embodiments, the X direction is also called the first direction, the Y direction is also called the second direction, and the Z direction is also called the third direction.

The first separation wall SLT1 includes two first separation parts P1 and two second separation parts P2 connected to each other at ends thereof. The first separation parts P1 extend in the X direction and are formed in the memory array region AR, the staircase region SR and the edge region ER. The second separation parts P2 extend in the Y direction and are formed in the edge region ER.

Multiple first separation walls SLT1 define multiple tiles T separated from each other, such as tiles T1, T2, T3 and T4. Each tile T may include a memory array region AR, a staircase region SR and an edge region ER. The staircase region SR is around the memory array region AR. The edge region ER is around the staircase region SR. The first separation wall SLT1 separates two tiles T from each other. Multiple separation walls SLT2 are formed in a tile T and therefore define multiple blocks B in each tile T. In FIG. 2B, each tile T includes three blocks B1, B2 and B3, but the embodiment of the present disclosure is not limited thereto.

Referring to FIG. 2B, multiple first separation walls SLT1 are separated from each other and may be arranged in an array of rows and columns to define a tile array including multiple tiles T1, T2, T3 and T4.

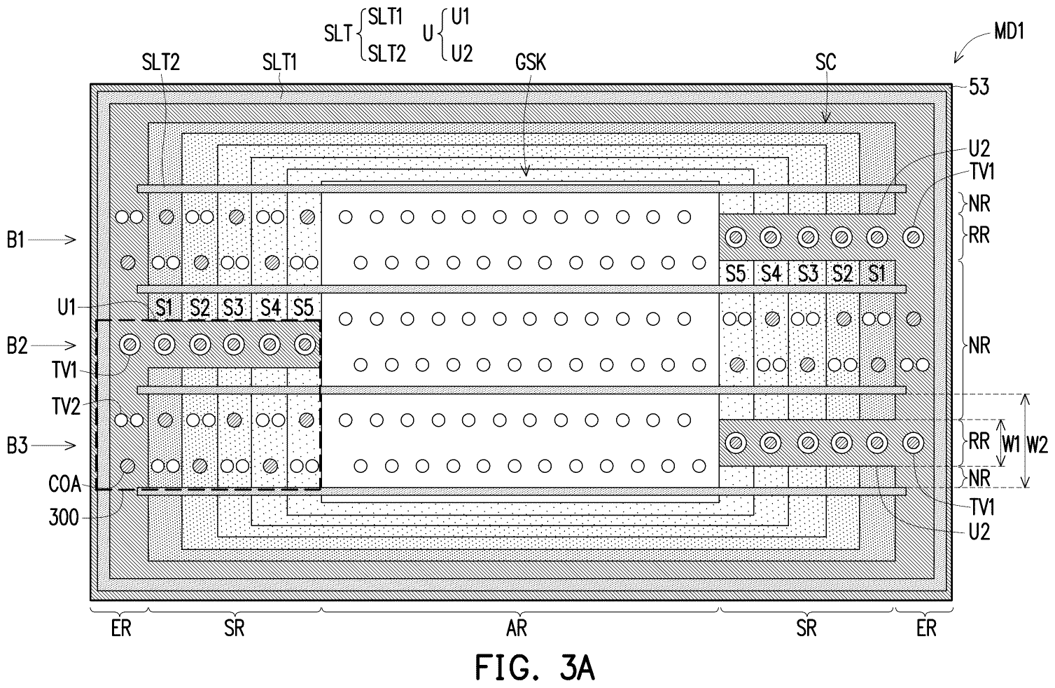

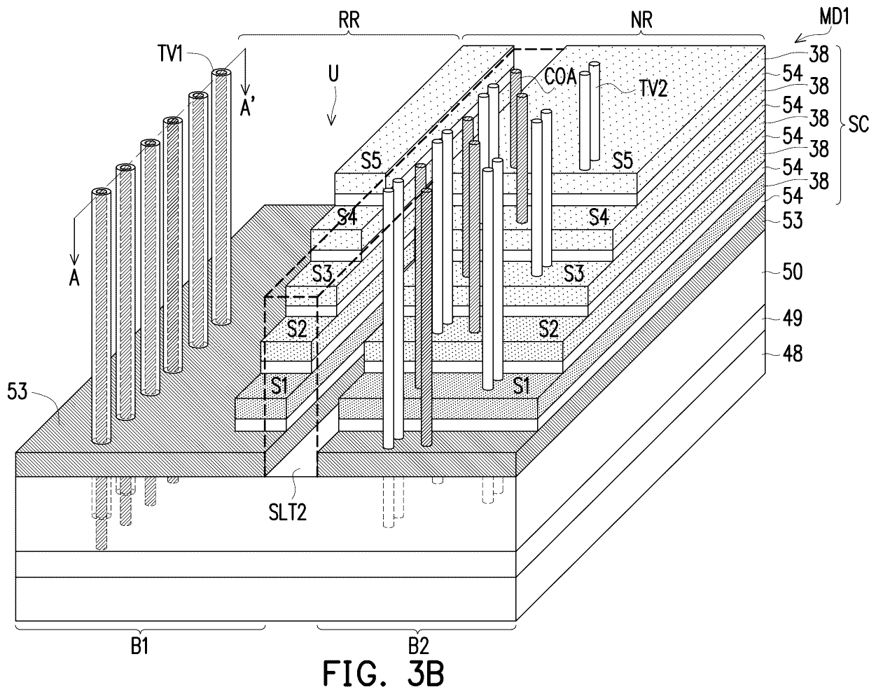

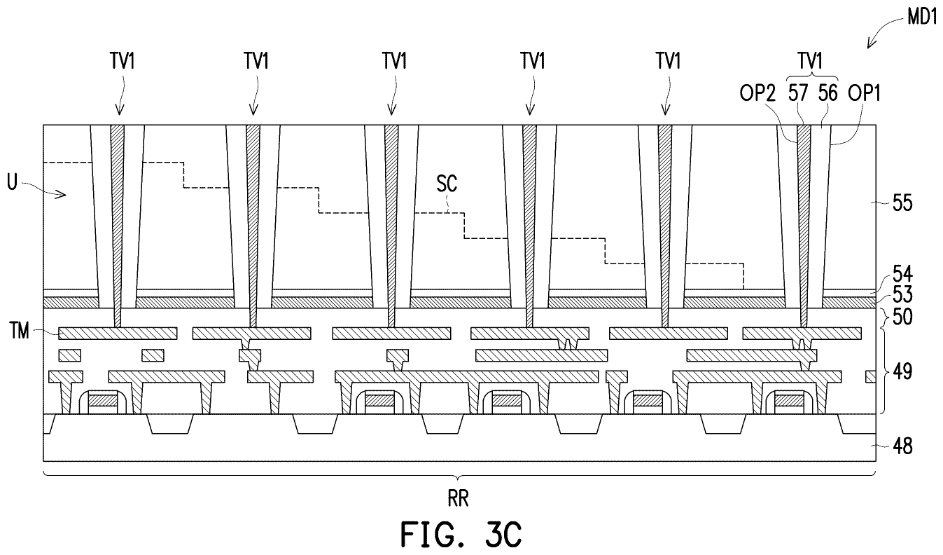

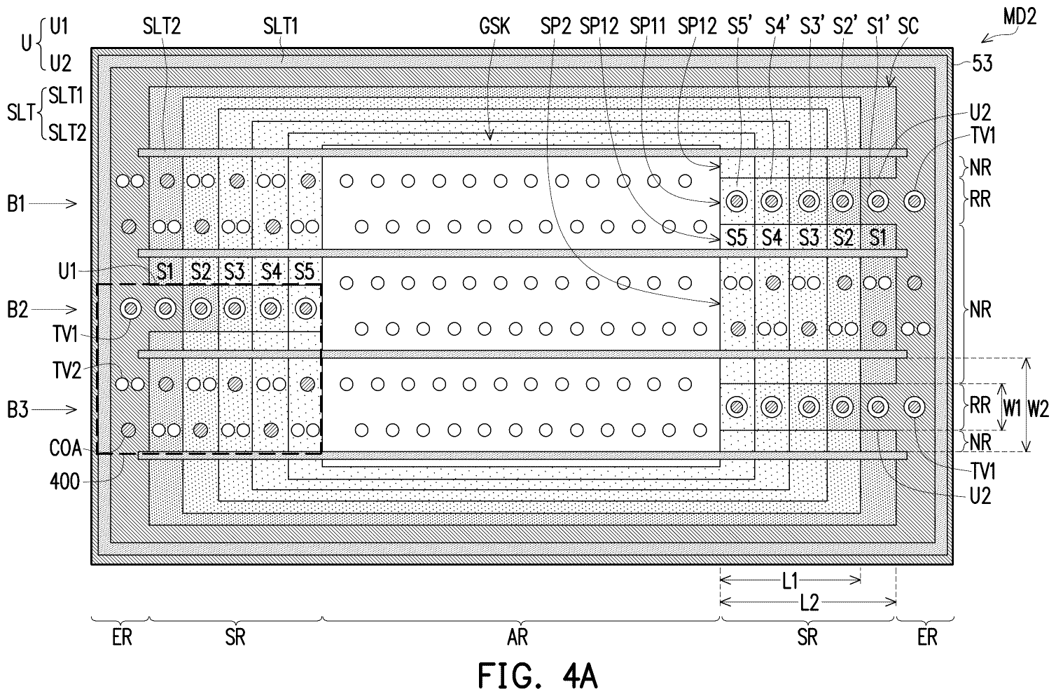

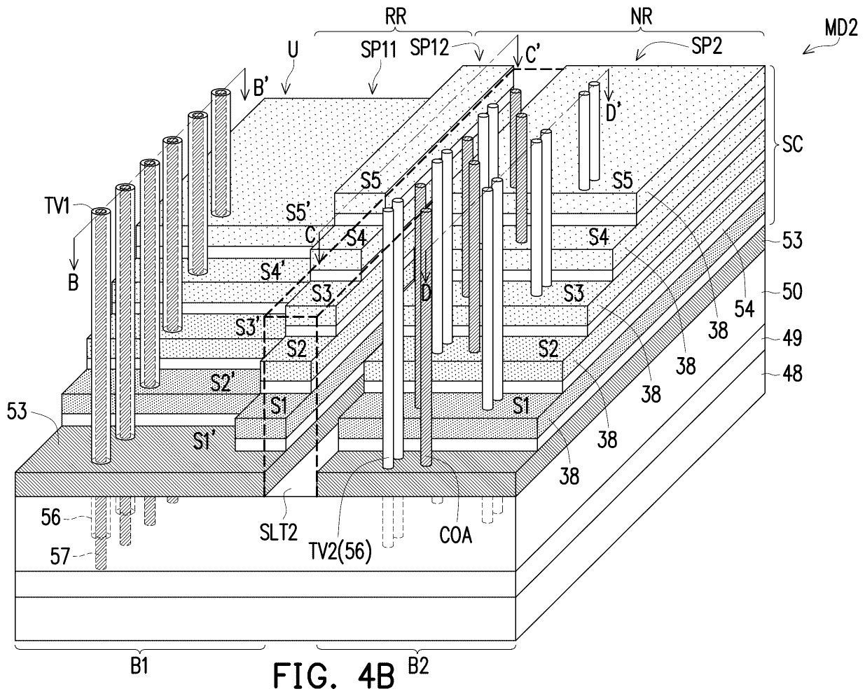

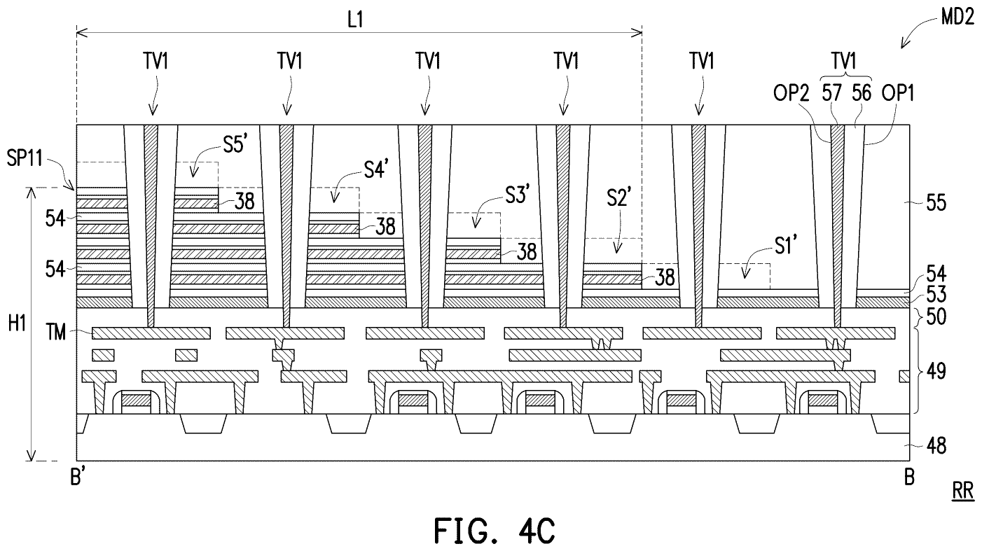

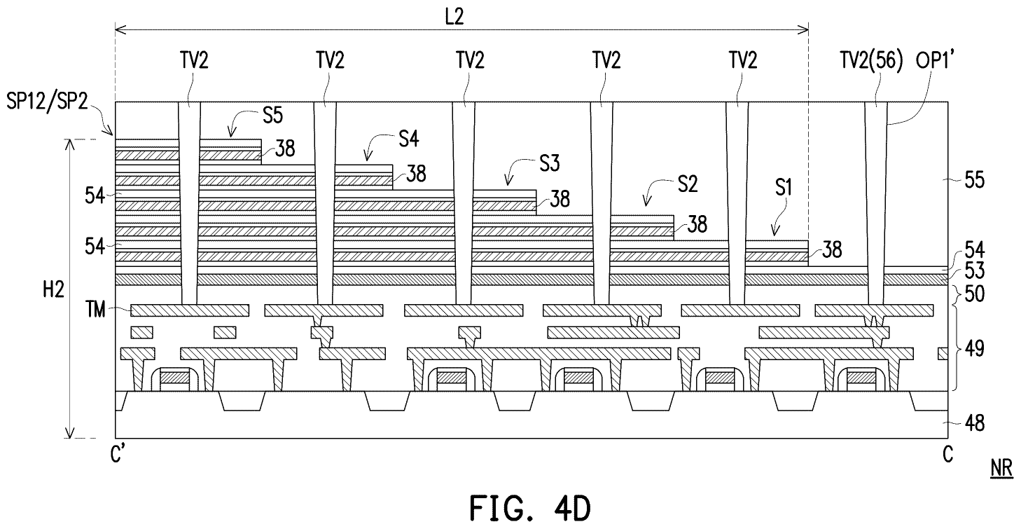

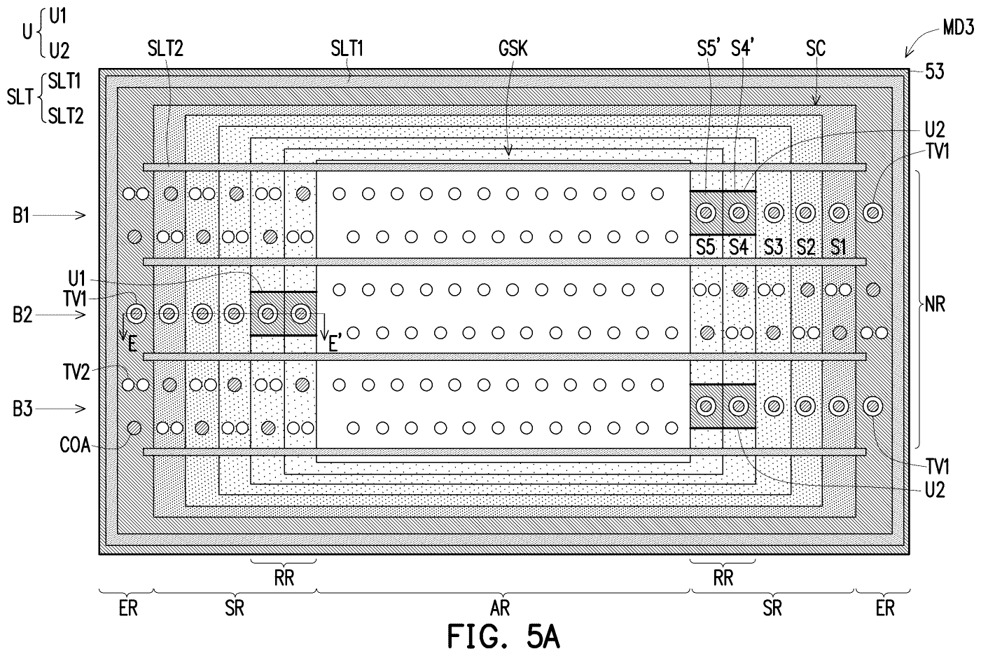

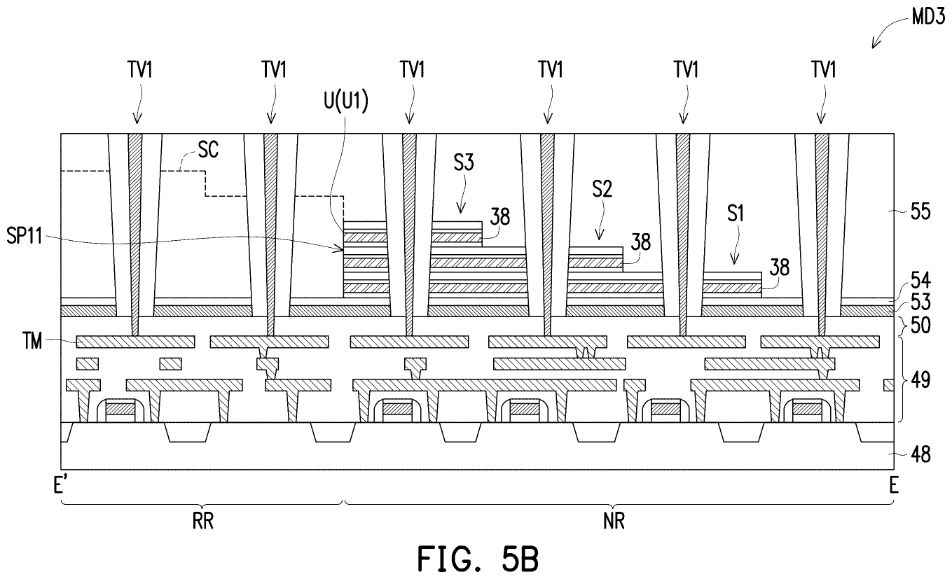

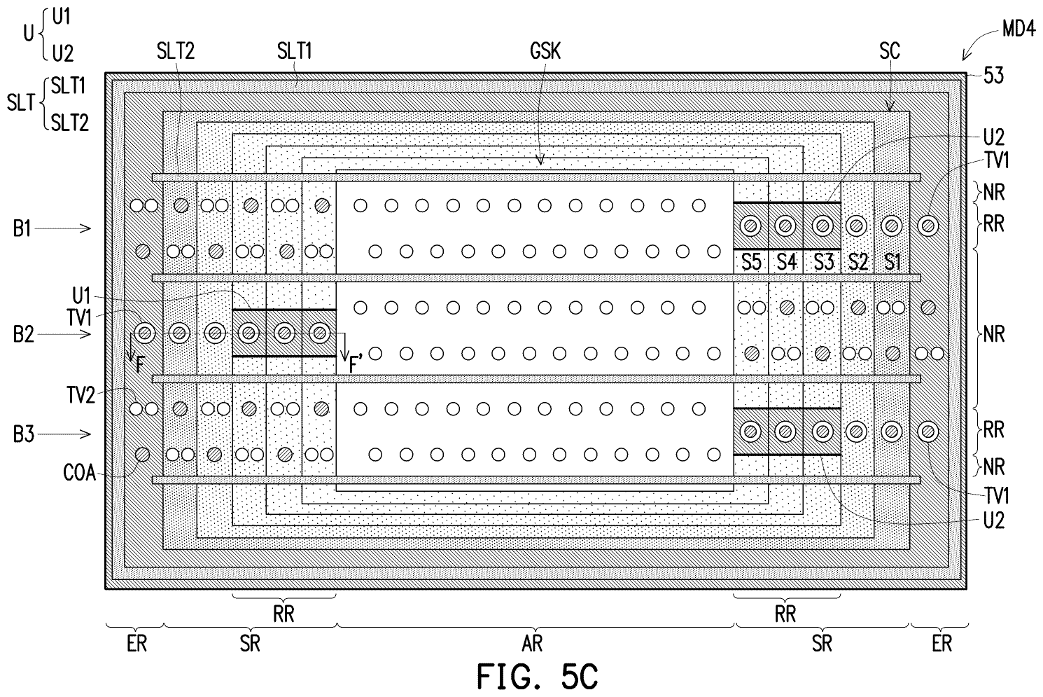

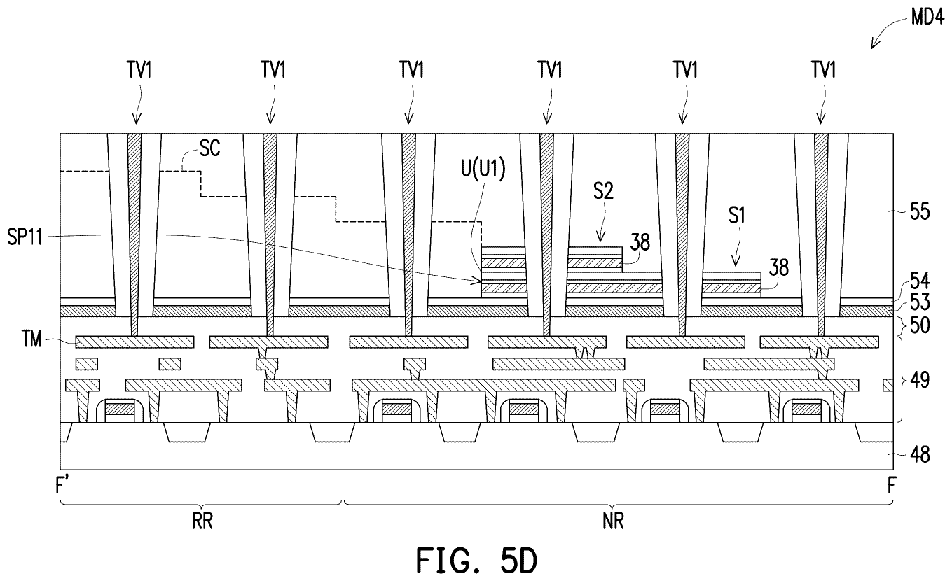

FIG. 3A is a top view of a memory device MID according to an embodiment of the present disclosure. FIG. 3B is a perspective view of a partial area 300 of FIG. 3A. FIG. 3C is a cross-sectional view taken along the line A-A′ of FIG. 3B. FIG. 4A is a top view of a memory device MD2 according to another embodiment of the present disclosure. FIG. 4B is a perspective view of a partial area 400 of FIG. 4A. FIG. 4C is a cross-sectional view taken along the line B-B′ of FIG. 4B. FIG. 4D is a cross-sectional view of the line C-C′ or D-D′ of FIG. 4B. FIG. 5A is a top view of a memory device MD3 according to yet another embodiment of the present disclosure. FIG. 5B is a cross-sectional view taken along the line E-E′ in FIG. 5A. FIG. 5C is a top view of a memory device MD4 according to yet another embodiment of the present disclosure. FIG. 5D is a cross-sectional view taken along the line F-F′ of FIG. 5C.

Referring to FIG. 2B, FIG. 3A, FIG. 4A, FIG. 5A, FIG. 5C, the present disclosure removes a part of the staircase structure SC to form multiple recesses U. The recesses U will be covered by the subsequently formed dielectric layer 55 (as shown in FIG. 3C, FIG. 4C, FIG. 5B and FIG. 5D). The recesses U include recesses U1 and recesses U2 staggered with each other, which are respectively located at opposite sides of the memory array region AR. In addition, adjacent recesses U of two adjacent tiles T are staggered with each other. For example, the recesses U2 of the tile T1 and the recess U1 of the tile T2 are staggered with each other, as shown in FIG. 2B.

Referring to FIG. 3A, FIG. 4A, FIG. 5A, and FIG. 5C, the region where the recesses U are formed is called a recess region RR, and the region where the recesses U are not formed is called a non-recess region NR. In some embodiments, the width W1 of the recess region RR is smaller than the width W2 of the block B. Therefore, the block B (such as block B1) of the staircase structure SC at one side (such as the right side) of the memory array region AR includes a recess region RR and a non-recess region NR, while the adjacent block B (such as block B2) of the staircase structure SC includes a non-recess region NR and is free of a recess region RR. In an embodiment of the present disclosure, the recesses U formed by partially removing the staircase structure SC are located in the recess region RR, and therefore, the height of the top surface of the recess region RR is lower than the height of the top surface of the non-recess region NR. In other embodiments (not shown), the width W1 of the recess region RR may be equal to the width W2 of the block B.

Referring to FIG. 2B, FIG. 3A, FIG. 4A, and FIG. 5A, the present disclosure removes a part of the staircase structure SC to form multiple recesses U in a recess region RR. The recesses U may be formed by removing high steps S5, S4, middle step S3, low steps S2, S1 or a combination thereof of the staircase structure SC. In some embodiments, the recesses U may be formed in all the steps of the staircase structure SC, as shown in FIG. 3A and FIG. 4A. In some other embodiments, the recesses U may be formed in a part of the steps, as shown in FIG. 5A and FIG. 5C.

Referring to FIG. 3A, the recesses U are formed in all the steps of the staircase structure SC; that is, each of the recesses U is formed in all the steps from the high step S5 to the low step S1. The recess U in the recess region RR extends continuously from the high step S5 to the low step S1 of the staircase structure SC. The staircase structure SC originally in the recess region RR is removed; and therefore, there is no staircase structure SC and no step in each recess U. The bottom surface of the recess U is a flat surface, exposing the conductive layer 53 (as shown in FIG. 3B), or exposing the insulating layer 54 above the conductive layer 53 (as shown in FIG. 3C). The recess U is covered by the subsequently formed dielectric layer 55 (as shown in FIG. 3C).

Referring to FIG. 4A and FIG. 4B, each of the recesses U is formed in all the steps (i.e., S5-S1) of the staircase structure SC. In the recess region RR, the recess U continuously extends from the high step S5 to the low step S1 of the staircase structure SC. The staircase structure below the recess U of the recess region RR is partially removed to form a stepped portion SP11. Therefore, the bottom surface of the recess U is a stepped surface, exposing the steps S5′, S4′, S3′, S2′, and S1′ of the stepped portion SP11 (as shown in FIG. 4B and FIG. 4C).

Referring to FIG. 4B, in the same block (e.g., block B1), there is a stepped portion SP11 in the recess region RR, and a stepped portion SP12 in the non-recess region NR. The adjacent block (e.g., block B2) has a stepped portion SP2 in the non-recess region NR, and is free of a recess region RR. The width of the stepped portion SP11 is equal to the width W1 of the recess region RR. The width of the stepped portion SP2 is equal to the width W2 of the block B2 (as shown in FIG. 4A).

Referring to FIG. 4C and FIG. 4D, in this embodiment, as compared with the steps S5, S4, S3, S2 and S1 (as shown in FIG. 4D) of the stepped portion SP12 or SP2 in the non-recess region NR, the steps S5′, S4′, S3′, S2′, and S1′ (as shown in FIG. 4C) of the stepped portion SP11 in the recess region RR are respectively reduced by one step. Therefore, the height H1 of the stepped portion SP11 of the recess region RR is smaller than the height H2 of the stepped portion SP12 or SP2 of the non-recess region NR. The top surface of the recess region RR is lower than the top surface of the non-recess region NR. The length L1 of the stepped portion SP11 of the recess region RR is less than the length L2 of the stepped portion SP12 or SP2 of the non-recess region NR, as shown in FIG. 4A.

However, the present disclosure is not limited thereto. In some other embodiments (not shown), as compared with the steps S5, S4, S3, S2 and S1 of the stepped portions SP12 and SP2 in the non-recess region NR, the steps S5′, S4′, S3′, S2′, and S1′ of the stepped portion SP11 in the recess region RR are respectively reduced by two or more steps. Alternatively, as compared with the steps S5, S4, S3, S2, and S1 in non-recess region NR, the steps S5′, S4′, S3′, S2′, and S1′ of the stepped portion SP11 in the recess region RR are reduced by different steps.

Referring to FIG. 5A, each of the recesses U is formed in a part of the steps (e.g., high steps S5 and S4) of the staircase structure SC. The recess U in the recess region RR extends from the high step S5 to the high step S4 of the staircase structure SC. Referring to FIG. 5B, the staircase structure SC originally in the recess region RR is removed, and therefore, there is no staircase structure SC in the recess U. Therefore, the bottom surface of the recess U is a flat surface, exposing the conductive layer 53 (not shown), or exposing the insulating layer above the conductive layer 53 (as shown in FIG. 5B). In the same block B (e.g., block B1), the middle step S3 and the low steps S2, S1 are not removed but remain in the non-recess region NR. Referring to FIG. 5A and FIG. 5B, in the same block (e.g., block B1) at one side (e.g., right side) of the memory array region AR, the top surface of the recess region RR is lower than the top surface of the non-recess region NR. As shown in FIG. 5B, among the adjacent blocks, the top surface of the recess region RR of the block B1 is lower than the top surface of the non-recess region NR of the adjacent block B2.

Referring to FIG. 5C, each of the recesses U is formed in a part of steps of the staircase structure SC. The recess U in the recess region RR is located in the high steps S5, S4 and the middle step S3 of the staircase structure SC. Referring to FIG. 5D, the staircase structure SC originally in the recess region RR is removed, and therefore, there is no staircase structure SC in the recess U, Therefore, the bottom surface of the recess U is a flat surface, exposing the conductive layer 53 (not shown), or exposing the insulating layer above the conductive layer 53 (as shown in FIG. 5B). The low steps S2, S1 are not removed but remain in the non-recess region NR. Referring to FIG. 5C and FIG. 5D, in the same block (e.g., block B1) at one side (e.g., right side) of the memory array region AR, the top surface of the recess region RR is lower than the top surface of the non-recess region NR. Referring to FIG. 5C, among the adjacent blocks, for example, the top surface of the recess region RR of the block B1 is lower than the top surface of the non-recess region NR of the adjacent block B2.

Referring to FIG. 3B, FIG. 4B, FIG. 5B and FIG. 5D, the recesses U may have vertical sidewalls or inclined sidewalls (not shown).

Referring to FIG. 3A to FIG. 3C, FIG. 4A to FIG. 4D, and FIG. 5A to FIG. 5D, the memory device includes multiple contacts COA, multiple through vias TV1 and multiple through vias TV2. Referring to FIG. 3B and FIG. 4B, multiple contacts COA are located in the non-recess region NR of the block B2, penetrate through the dielectric layer 55, and are landed on the stepped portion SP2 of the staircase structure SC. The contacts COA include conductive materials, and are electrically connected to the conductive layers 38 or the barrier layers of the steps S1-S5 of the stepped portion SP2, respectively. In some embodiments, the diameter of the through vias TV1 is greater than the diameter of the through vias TV2 or/and greater than the diameter of the contacts COA.

Referring to FIG. 3B, FIG. 4B and FIG. 4D, multiple through vias TV2 are located in the non-recess region NR of the block B2, penetrate through the dielectric layer and the stepped portion SP2 of the staircase structure SC, and extend to the conductive layer 53. Each through via TV2 includes an insulating layer, and is electrically isolated from the conductive layer 38 of the staircase structure SC and electrically isolated from the interconnection structure 49. Therefore, the through vias TV2 are also called insulating through vias TV2.

Referring to FIG. 3B, FIG. 4B, FIG. 4C, FIG. 5B and FIG. 5D, multiple through vias TV1 are located in the recess region RR of the block B1, penetrate through the dielectric layer 55 and extend to the conductive layer 53 and the interconnection structure 49, and are landed on and electrically connected to the topmost conductive layer TM of the interconnection structure 49. Therefore, the through vias TV1 are also called conductive through vias TV1. Each through via TV1 includes an insulating layer 56 and a conductive via 57. The insulating layer 56 penetrates through the dielectric layer 55 and extends through the conductive layer 53. The conductive via 57 is located in the insulating layer 56 and penetrates through the insulating layer 56 and the dielectric layer 50, and is landed on and electrically connected to the topmost conductive layer TM of the interconnection structure 49.

Referring to FIG. 3C, the insulating layer 56 of each of through vias TV1 penetrates through the dielectric layer 55 to the conductive layer 53, without penetrating through any of the staircase structure SC. Referring to FIG. 4C, the insulating layer 56 of each of the through vias TV1 penetrates through the dielectric layer 55, the stepped portion SP11 of the staircase structure SC to the conductive layer 53. Referring to FIG. 5B and FIG. 5D, the insulating layer 56 of each of the through vias TV1 in the recess region RR penetrates through the dielectric layer 55 to the conductive layer 53, without penetrating through any of the staircase structure SC. The insulating layer 56 of each of the through vias TV1 in the non-recess region NR penetrates through the dielectric layer 55, the middle step S3, the low steps S2, and S1 of the staircase structure SC to the conductive layer 53. The number of layers of the staircase structure SC penetrated by the insulating layer 56 of the through vias TV1 is less than the number of layers of the staircase structure SC penetrated by the through vias TV2, or the through vias TV1 do not penetrate through any of the staircase structure SC. The insulating layer 56 of the through via TV1 penetrates fewer layers of the staircase structure SC, so the issue of etching more conductive layers of the staircase structure SC and therefore forming a first opening OP1 having an excessively inclined sidewall for the through via TV1 can be avoided. The sidewall of the first opening OP1 is excessively inclined, resulting in excessive insulating layer remaining at the bottom of the first opening OP1. As a result, the “open” issue that excessive insulating layer remaining at the bottom of the first opening OP1 causes insufficient etching (for forming a second opening OP2 for the through via TV1) unable to reach the topmost conductive layer TM of the interconnection structure 49 can be avoided.

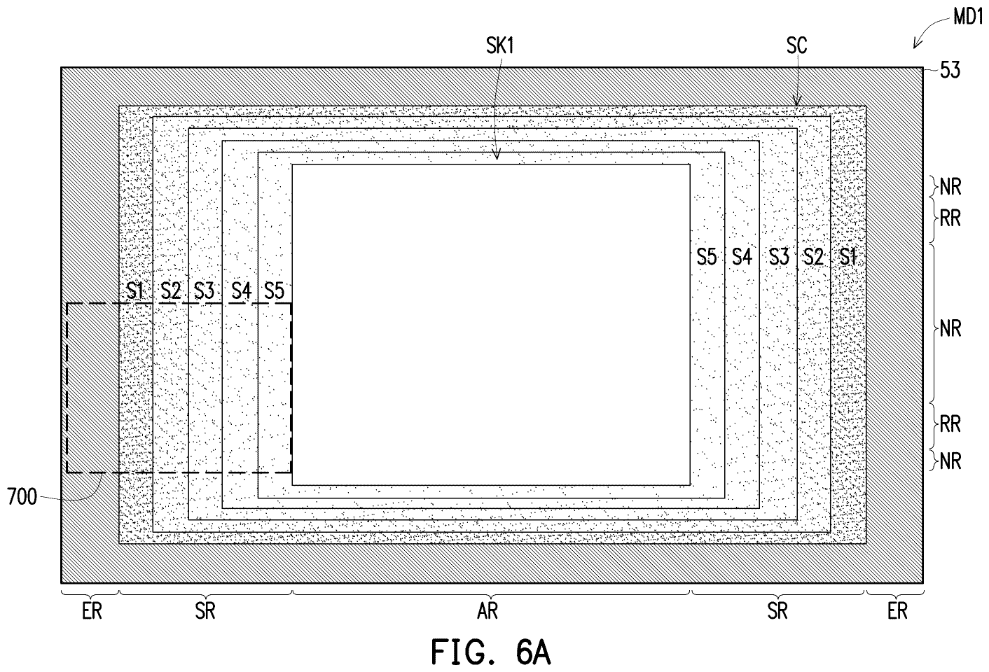

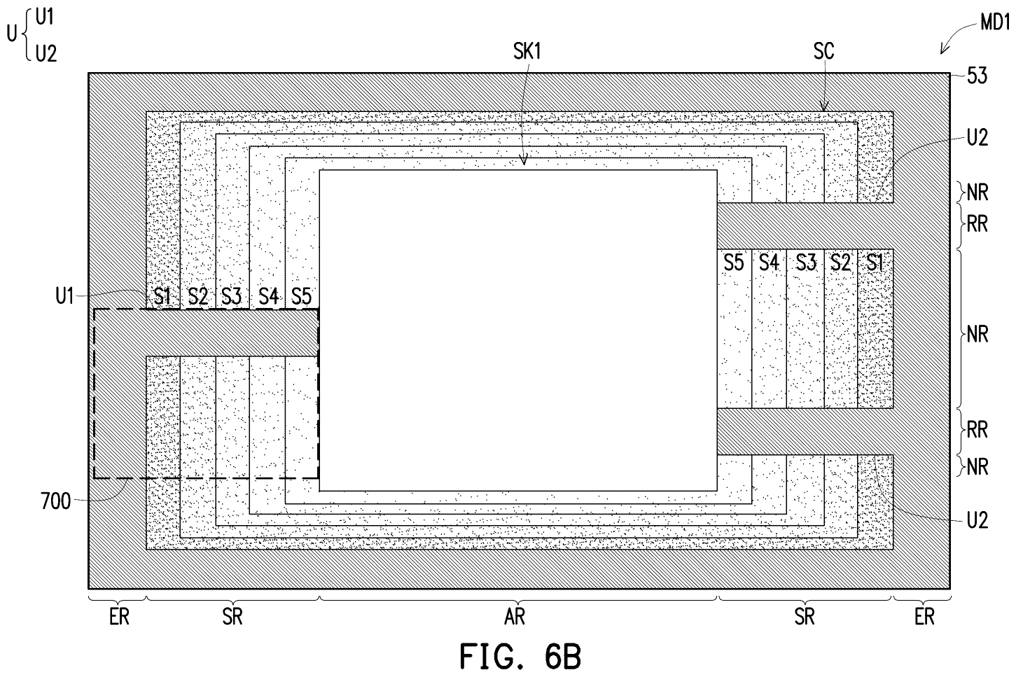

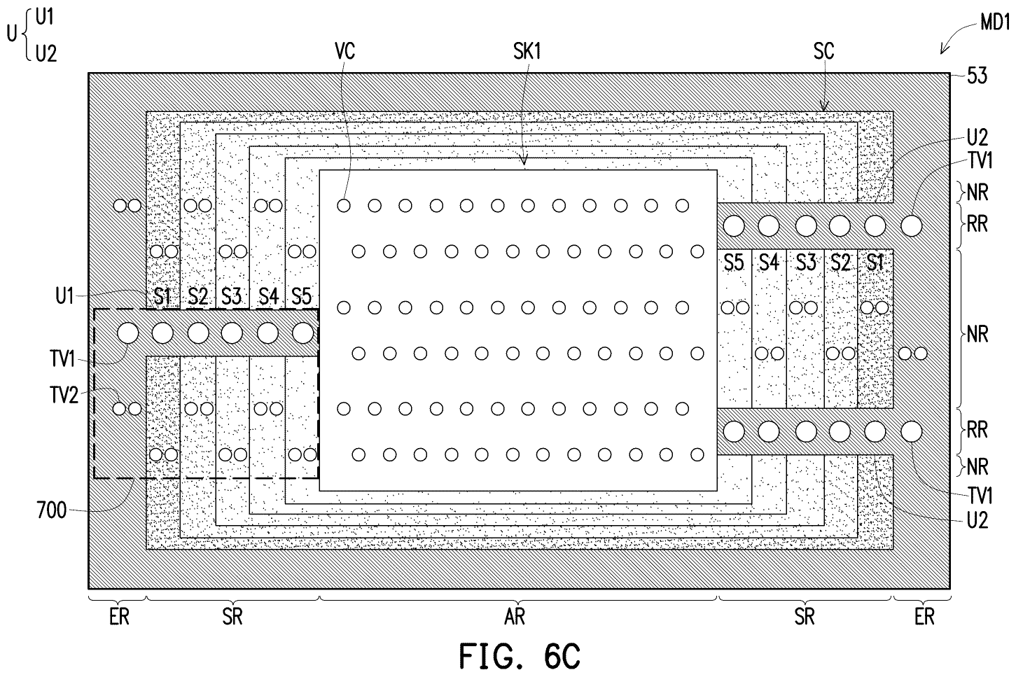

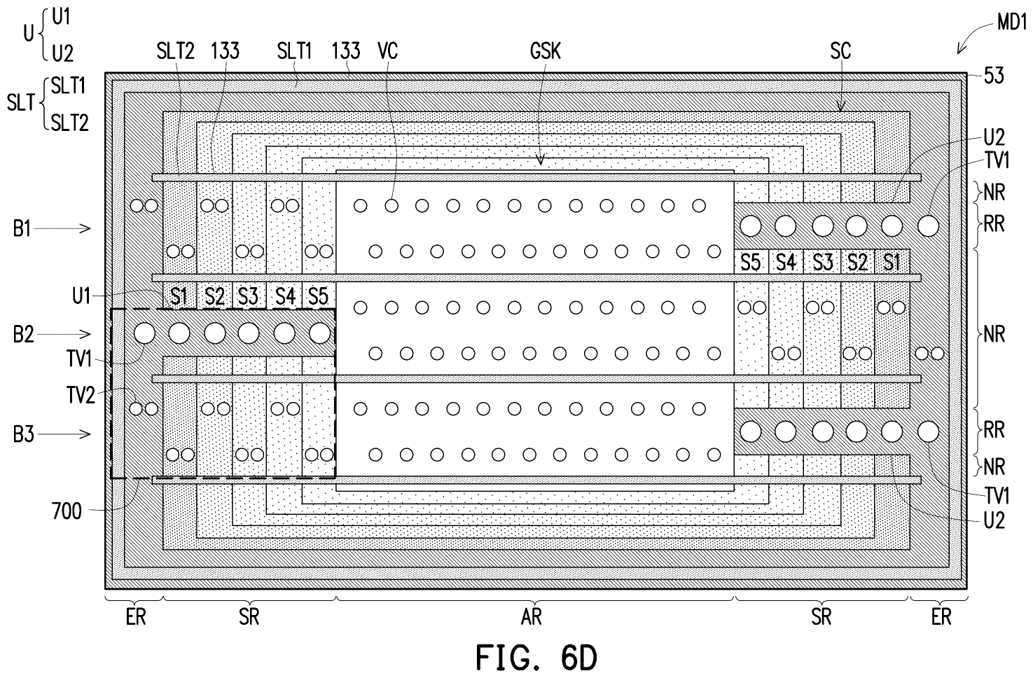

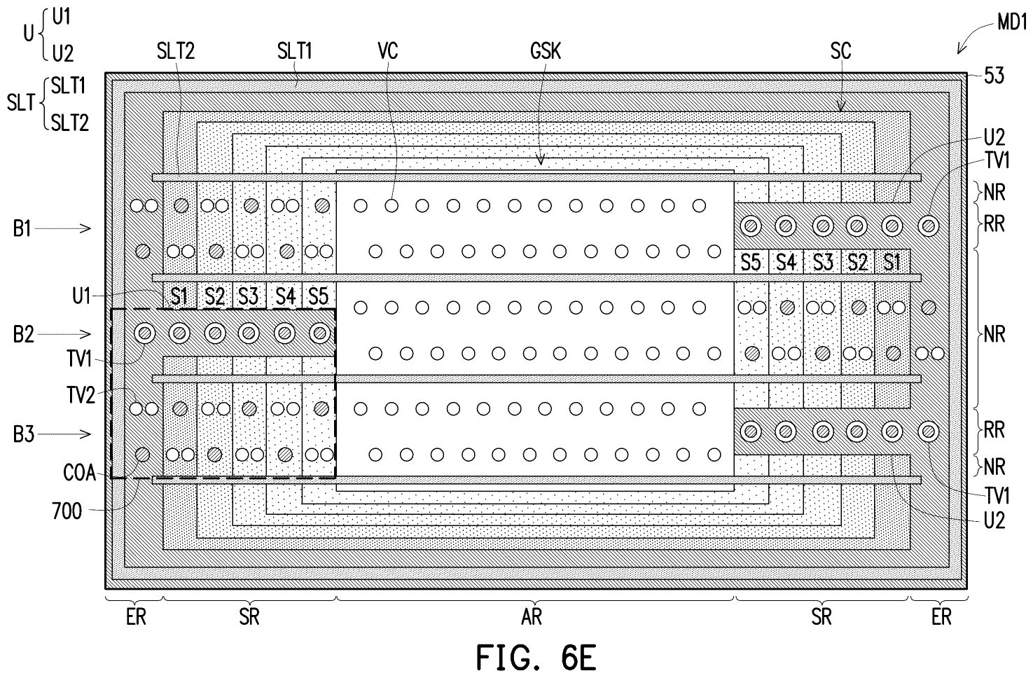

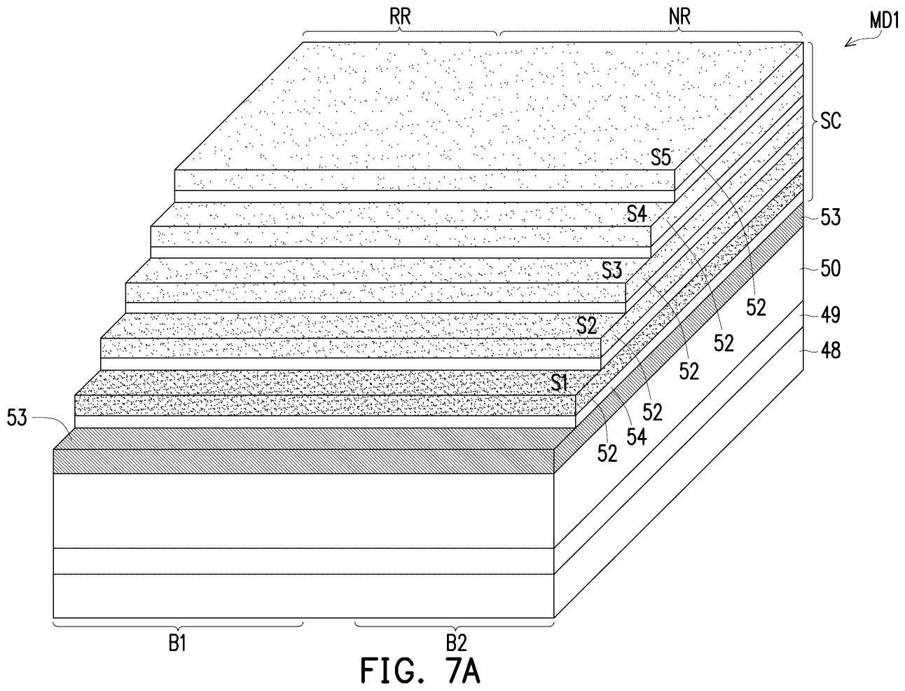

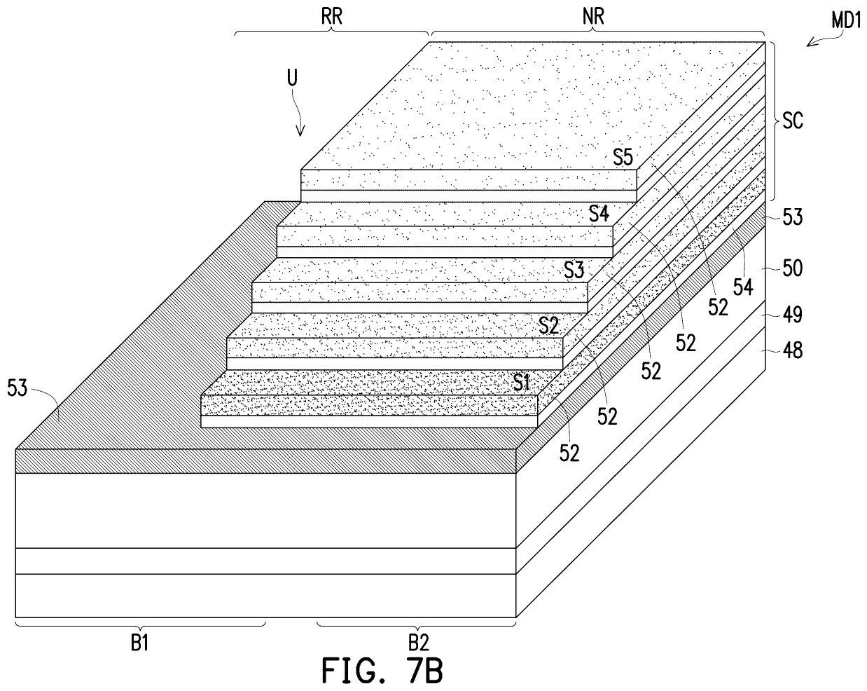

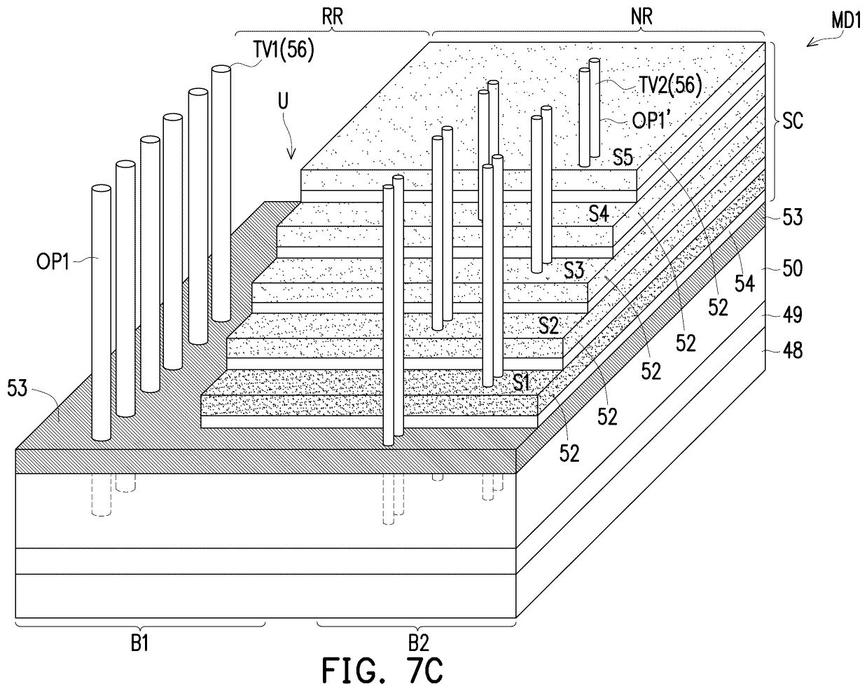

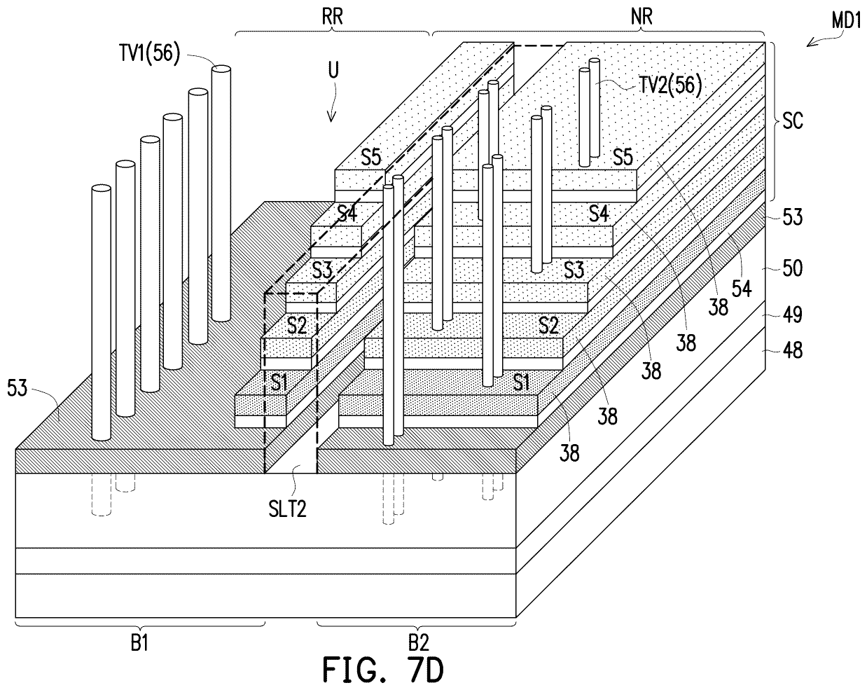

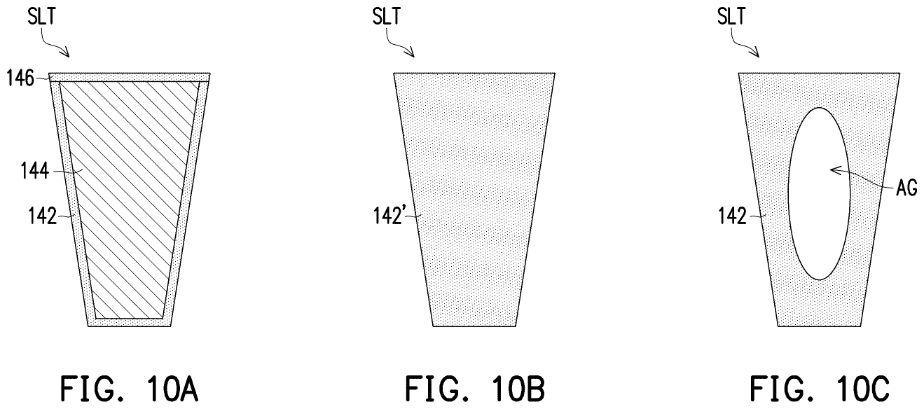

FIG. 6A to FIG. 6E are schematic cross-sectional views of a method of fabricating the memory device of FIG. 3A. FIG. 7A to FIG. 7E are perspective views of a partial area 700 in FIG. 6A to FIG. 6E. FIG. 10A to FIG. 10C are schematic cross-sectional views of various separation structures according to embodiments of the present disclosure.

Referring to FIG. 6A and FIG. 7A, a substrate 48 is provided. The substrate 48 includes an array region AR, a staircase region SR and an edge region ER. The substrate 48 may include a semiconductor substrate, such as a silicon substrate. The substrate 48 may include components such as active elements (such as PMOS, NMOS, CMOS, JFET, BJT, or diodes) or passive elements. An interconnection structure 49 is formed on the array region AR and the staircase region SR of the substrate 48. The interconnection structure 49 may include components such as an intra-layer dielectric layer, a contact, a wire, an interlayer dielectric layer, and a via. The material of each of the intra-layer dielectric layer and the interlayer dielectric layer may include a silicon oxide layer. Next, a dielectric layer 50 is formed on the interconnection structure 49. The material of the dielectric layer 50 may include silicon oxide. In some embodiments, the dielectric layer 50 may also be referred to as a dielectric substrate 50.

Continue referring to FIG. 6A and FIG. 7A, a blanket-type conductive layer 53 is formed on the dielectric layer 50 in the array region AR and the staircase region SR. The conductive layer 53 also extends to the edge region ER. The conductive layer 53 may include a grounded P-type doped polysilicon layer. The conductive layer 53 can also be called a dummy gate, which can be used to close a leakage path.

Referring to FIG. 6A and FIG. 7A, a stacked structure SK1 is formed on the conductive layer 53, and the stacked structure SK1 is patterned to form a staircase structure SC in the staircase region SR. In this embodiment, the stacked structure SK1 includes insulating layers 54 and the intermediate layer 52 that are sequentially alternately stacked on the conductive layer 53. In other embodiments, the stacked structure SK1 may be composed by intermediate layers 52 and insulating layers 54 that are sequentially alternately stacked on the conductive layer 53. In addition, in this embodiment, the uppermost layer of the stacked structure SK1 is the insulating layer 54. The material of the insulating layers 54 may include silicon oxide. The material of the intermediate layers 52 may include silicon nitride. The intermediate layers 52 can be used as sacrificial layers, which are partially removed in the subsequent processes. In this embodiment, the stacked structure SK1 has five insulating layers 54 and four intermediate layers 52, but the disclosure is not limited thereto. In other embodiments, more insulating layers 54 and more intermediate layers 52 may be formed according to actual needs.

Referring to FIG. 6B and FIG. 7B, a mask layer (not shown) is formed on the substrate 48 to expose a recess region RR. The mask layer may include a photoresist layer. Then, lithography and etching processes are performed to remove a part of the staircase structure SC to form recesses U. The etching process may include an anisotropic etching process. The mask layer is then removed. In this embodiment, each of the recesses U exposes the conductive layer 53 (as shown in FIG. 6B and FIG. 7B). During the etching, the conductive layer 53 may serve as an etching stop layer.

A dielectric layer 55 (as shown in FIG. 3C) is formed on the substrate 48 to cover the staircase structure SC and the recesses U. The material of the dielectric layer 55 may include silicon oxide. The method of forming the dielectric layer 55 may include forming a dielectric material to fill the staircase structure SC. Afterwards, a planarization process is performed by chemical mechanical polishing process, for example. For clarity, the dielectric layer 55 is not shown in FIG. 6B and FIG. 7B.

Referring to FIG. 6C, multiple openings VC are formed in the stacked structure SK1. The openings VC expose the conductive layer 53. The etching process may include a dry etching process, a wet etching process or a combination thereof. The dry etching process may include a plasma etching process. In this embodiment, from the top view, the opening VC has a circular shape, but the disclosure is not limited thereto. In other embodiments, the opening VC may have other shapes, such as a polygon shape (not shown). Next, in some embodiments, the tunneling layer 14 and the channel pillar 16 are formed in the opening VC, as shown in FIG. 1D and FIG. 1E. The tunneling layer 14 may be formed in the subsequent processes. For simplicity, the channel pillar 16 and the tunneling layer 14 are not shown in FIG. 6C.

Referring to FIG. 1D and FIG. 1E, the tunneling layer 14 and the channel pillar 16 may penetrate through the stacked structure SK1 but do not penetrate through the conductive layer 53, but the present disclosure is not limited thereto. The channel pillar 16 may be annular from a top view, and may be continuous in its extending direction (e.g., in a direction perpendicular to the surface of the substrate 48). That is to say, the channel pillar 16 is integral in its extending direction, and is not divided into multiple disconnected parts. In some embodiments, the channel pillar 16 may have a circular shape from a top view, but the present disclosure is not limited thereto. In other embodiments, the channel pillar 16 may also have other shapes (such as polygonal shape) from a top view.

Referring to FIG. 1D and FIG. 1E, an insulating filling material is formed on the stacked structure SK1 and filled in the openings VC. The insulating filling material may include low-temperature silicon oxide. The insulating filling material filled in the opening VC forms an insulating filling layer 24, and a circular void is left at the center of the insulating filling layer 24. Then, an anisotropic etching process is performed to enlarge the circular void to form a hole 109. An insulating material is formed on the insulating fill layer 24 and filled in the hole 109. Then, an anisotropic etching process is performed to remove a part of the insulating material to form an insulating pillar 28 in the hole 109. The material of the insulating pillar 28 is different from the material of the insulating filling layer 24. The material of the insulating pillar 28 may include silicon nitride.

Referring to FIG. 1D and FIG. 1E, a patterning processes (e.g., lithography and etching processes) is performed to form holes (not shown) in the insulating filling layer 24. During the etching process, the conductive layer 53 may serve as an etching stop layer. Therefore, the formed holes extend from the stacked structure SK1 to the exposed conductive layer 53. The profiles of the hole patterns defined in the patterning process may be tangent to the profile of the insulating pillar 28. The profiles of the hole patterns defined in the patterning process may also exceed the profile of the insulating pillar 28 (not shown).

Referring to FIG. 1D and FIG. 1E, conductive pillars 32a and 32b are formed in the holes. The conductive pillars 32a and 32b may serve as source and drain pillars respectively, and are electrically connected to the channel pillar 16 respectively. The conductive pillars 32a and 32b can be formed by forming a conductive layer on the insulating filling layer 24 and in the holes, and followed by an etching back. The conductive pillars 32a and 32b may include doped polysilicon.

Referring to FIG. 6C and FIG. 7C, lithography and etching processes are performed to form the first openings OP1 and OP1′. The size of the first opening OP1 may be greater than the size of the first opening OP1′. Since there is no need to penetrate through any of the staircase structure SC during the etching process of the first opening OP1, the difficulty of etching can be reduced, and problems caused by excessively inclined sidewalls of the first openings OP1 can be avoided. Afterwards, an insulating material is filled in the first openings OP1 and OP1′ to form an insulating layer 56 of the through vias TV1 and TV2. The insulating material may include silicon oxide.

Referring to FIG. 6D and FIG. 7D, the stacked structure SK1 and the conductive layer 53 are patterned to form multiple separation trenches 133. During the etching process, the dielectric layer 50 or the conductive layer 53 may serve as an etching stop layer, so that the separation trenches 133 expose the dielectric layer 50 or the conductive layer 53. The etching process may include a dry etching process, such as a plasma etching process.

Referring to FIG. 6D and FIG. 7D, a replacement process is performed to the intermediate layers 52. First, an etching process such as a wet etching process is performed to remove a part of the intermediate layers 52 to form multiple horizontal openings (not shown). Multiple charge storage layers 12, multiple barrier layers 36 and multiple conductive layers 38 are respectively formed in multiple horizontal openings, as shown in FIG. 7D. The charge storage layers 12 may include silicon nitride. The blocking layers 36 may include a material having a high dielectric constant greater than or equal to 7, such as aluminum oxide (Al₁O₃), hafnium oxide (HfO₂), lanthanum oxide (La₂O₅), transition metal oxide, lanthanide oxide or a combination thereof. The conductive layers 38 may include tungsten. In some embodiments, multiple barrier layers (not shown) are also formed prior to the formation of the conductive layers 38. The material of the barrier layers may include titanium (Ti), titanium nitride (TiN), tantalum (Ta), tantalum nitride (TaN) or a combination thereof.

Referring to FIG. 6D and FIG. 7D, the method of forming the charge storage layer 12, the blocking layer 36, the barrier layer and the conductive layer 38 includes sequentially forming a storage material, a blocking material, a barrier material and a conductive material in the separation trenches 133 and the horizontal openings. Then, an etching back process is performed to remove the storage material, the blocking material, the barrier material and the conductive material in the separation trenches 133. The tunneling layer 14, the charge storage layer 12 and the blocking layer 36 are collectively referred to as a charge storage structure 40. The gate stacked structure GSK is thus formed. The gate stacked structure GSK is disposed on the substrate 48 and includes multiple conductive layers 38 and multiple insulating layers 54 stacked alternately.

Referring to FIG. 6D and FIG. 7D, the separation structures SLT are formed in the separation trenches 133. The separation structures SLT include multiple first separation walls SLT1 and multiple second separation walls SLT2. The first separation walls SLT1 separate the stacked structure SK1 and the conductive layer 53 into multiple tiles T (e.g., tiles T1, T2, T2, T4 as shown in FIG. 2B). Multiple second separation walls SLT2 divide each tile T into multiple blocks B (e.g., B1, B2, B3). Each of the separation structures SLT may have a single-layer or multi-layer structure, as shown in FIG. 10A to FIG. 10C.

Referring to FIG. 6D, FIG. 7D and FIG. 10A, in some embodiments, the method of forming the separation structures SLT are described as follows. An insulating liner material and a conductive material are filled on the gate stacked structure GSK and in the separation trenches 133. The insulating liner material may include silicon oxide. The conductive material may include polysilicon. Then, excess insulating liner material and conductive material on the gate stacked structure GSK and the edge region ER are removed through an etching back process or a planarization process, so as to form a liner layer 142 and a conductive layer 144. Afterwards, a dielectric material is formed on the substrate 48, and then an etching back process or a planarization process may be performed to planarize the dielectric material to form a dielectric layer 146. The liner layer 142, the conductive layer 144 and a part of the dielectric layer 146 form a separation structure SLT, as shown in FIG. 10A.

In some embodiments, the separation structure SLT may also be completely filled with an insulating material 142′, without any conductive material, as shown in FIG. 10B. In some other embodiments, the separation structure SLT may include a liner 142 covering an air gap AG, without any conductive material, as shown in FIG. 10C.

Referring to FIG. 3C, FIG. 6E and FIG. 7E, conductive vias 57 are formed in the insulating layer 56 of the through vias TV1, and contacts COA are formed. The conductive vias 57 are located in the insulating layer 56 and extend through the insulating layer 56 and the dielectric layer 50, landed on and electrically connected to the topmost conductive layer TM of the interconnection structure 49. The contacts COA are landed on the conductive layers 38. The method for forming the conductive vias 57 includes performing lithography and etching processes to form multiple second opening OP2 in the insulating layer 56. The second openings OP2 penetrate through the insulating layer 56 and the dielectric layer 50, exposing the topmost conductive layer TM of the interconnection structure 49. Next, a conductive material is formed on the substrate 48, and the conductive material is filled in the second openings OP2. The conductive material may include tungsten or polysilicon. Afterwards, a planarization process such as a chemical mechanical polishing process is performed to remove the conductive material outside the via holes. The contacts COA can be formed by a method similar to that of the conductive via 57 or any known method.

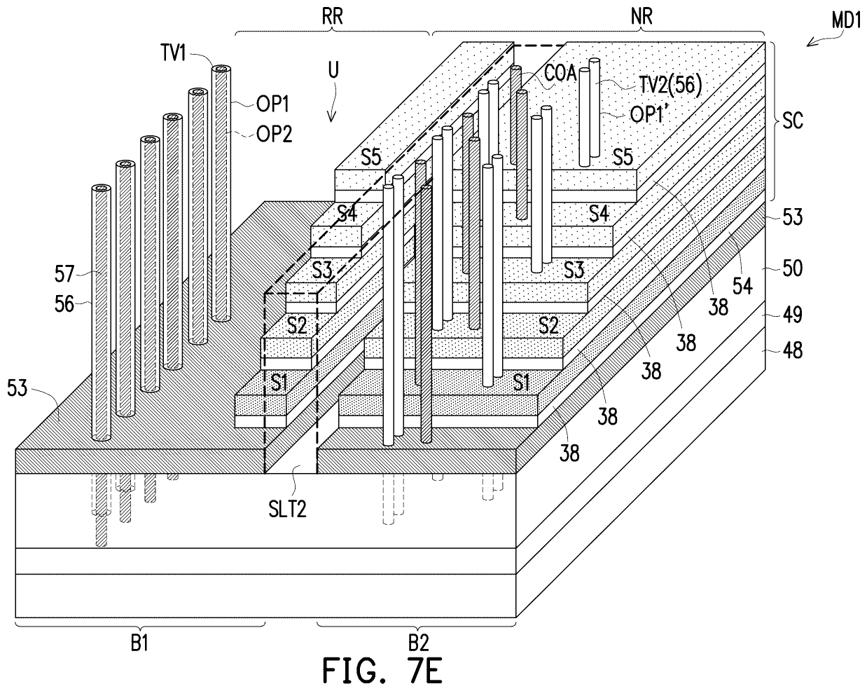

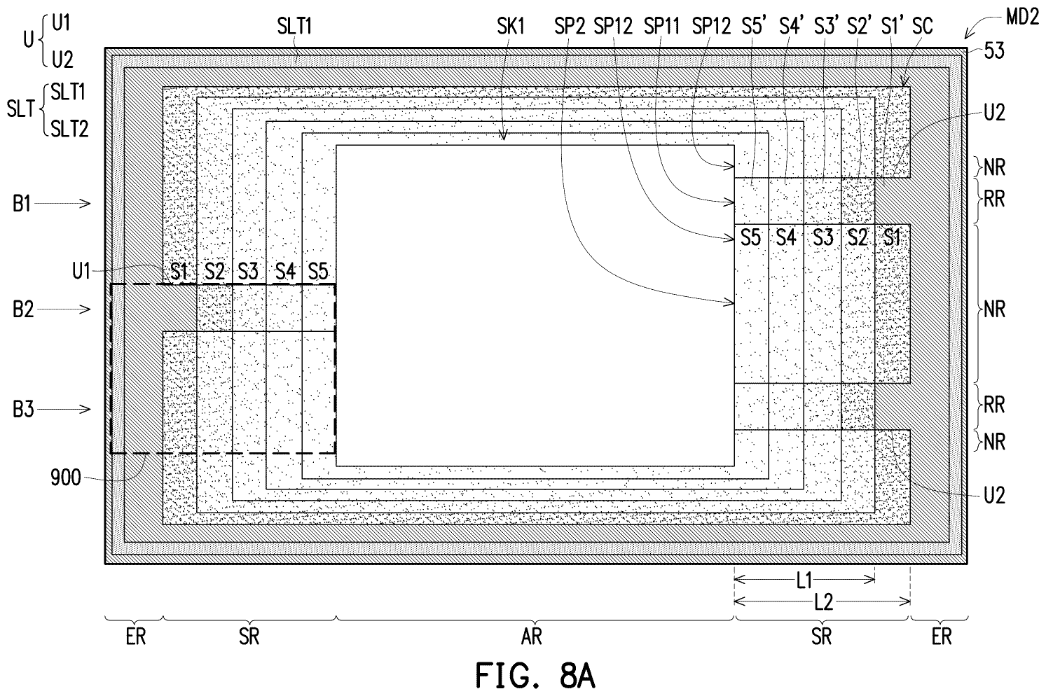

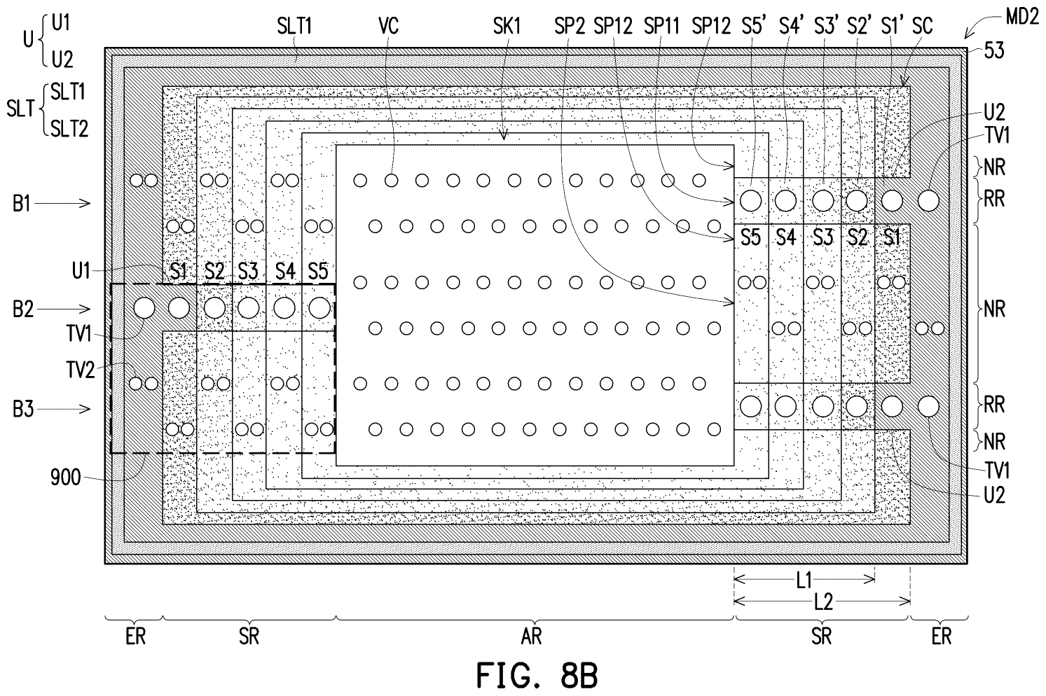

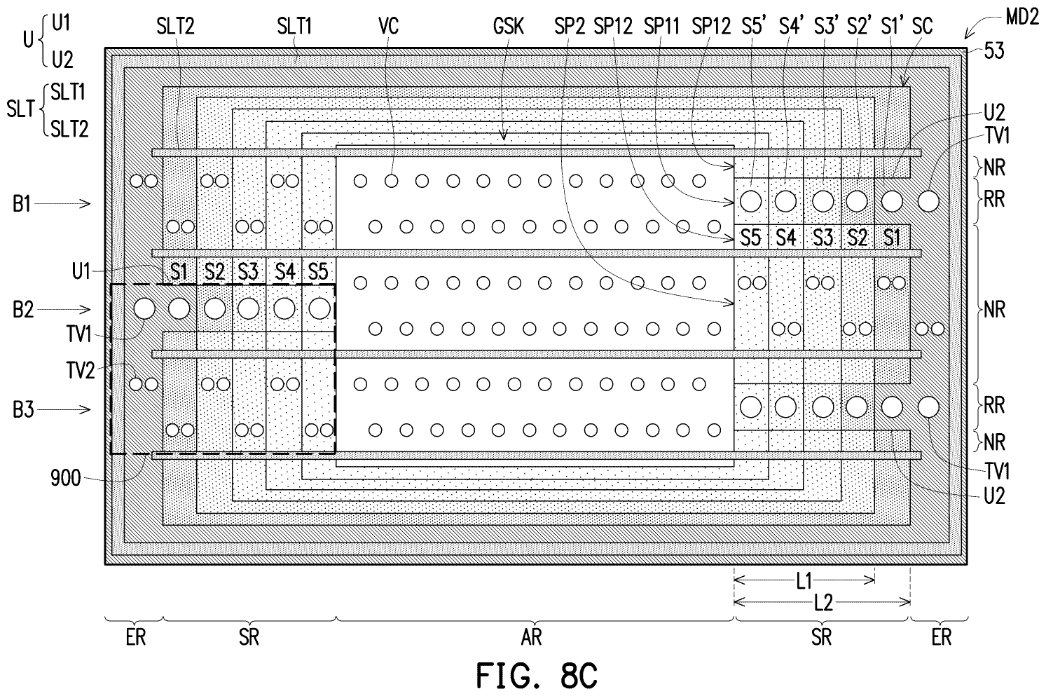

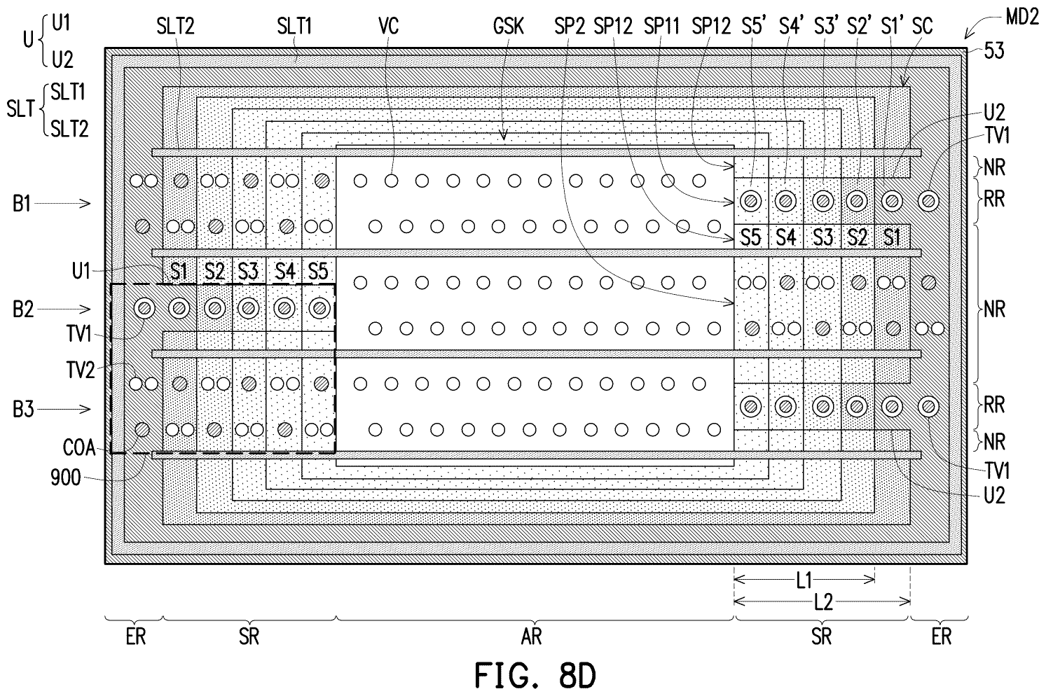

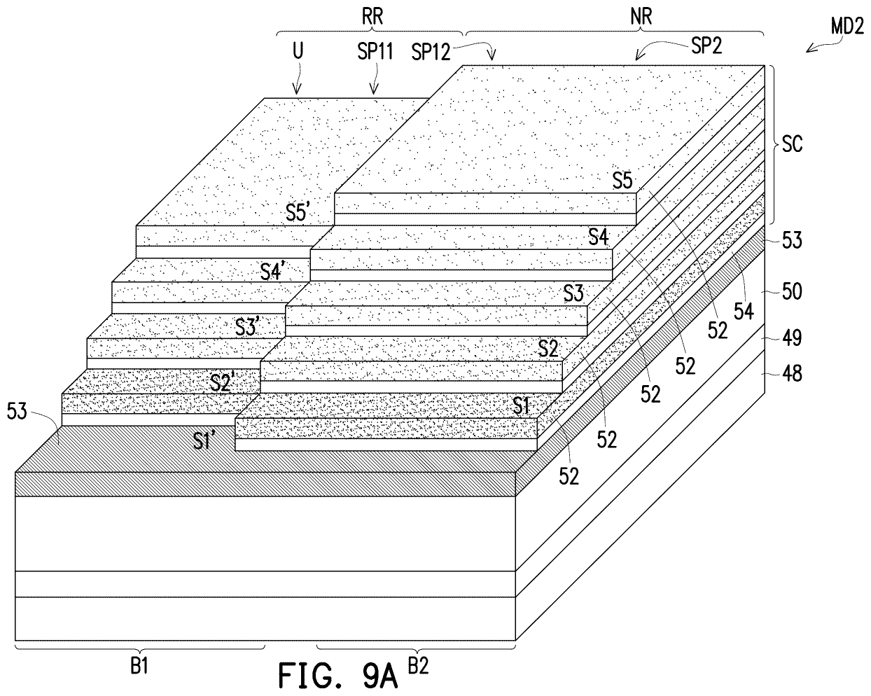

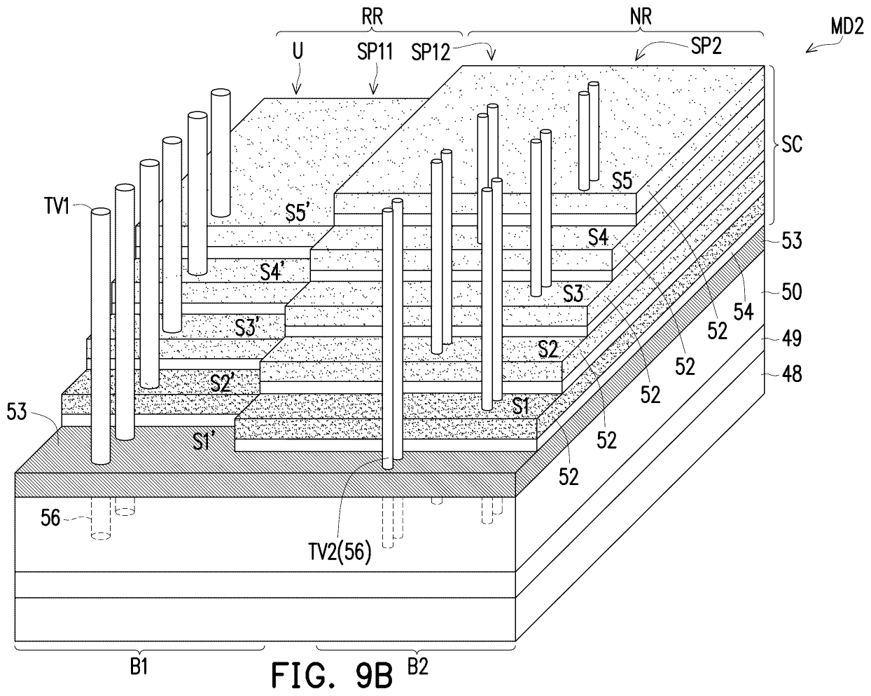

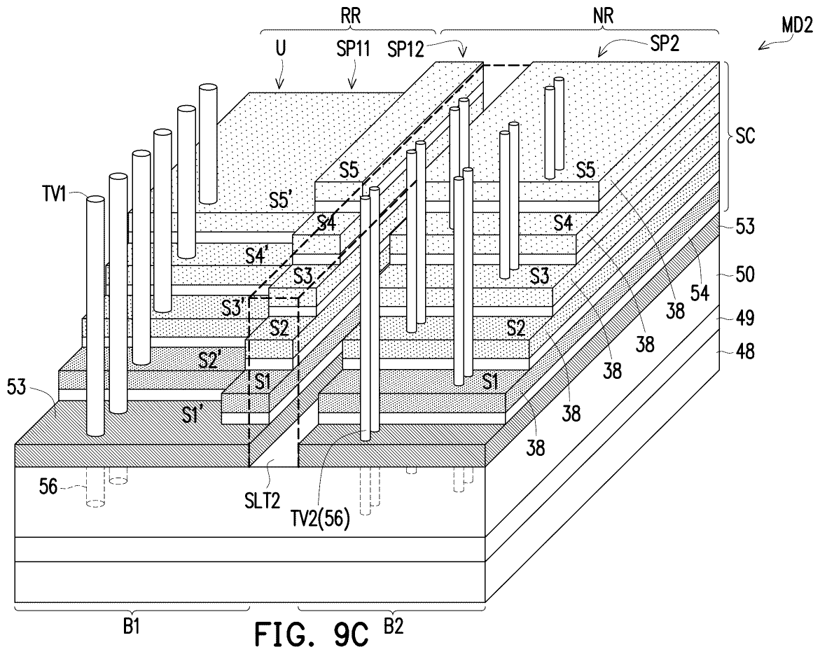

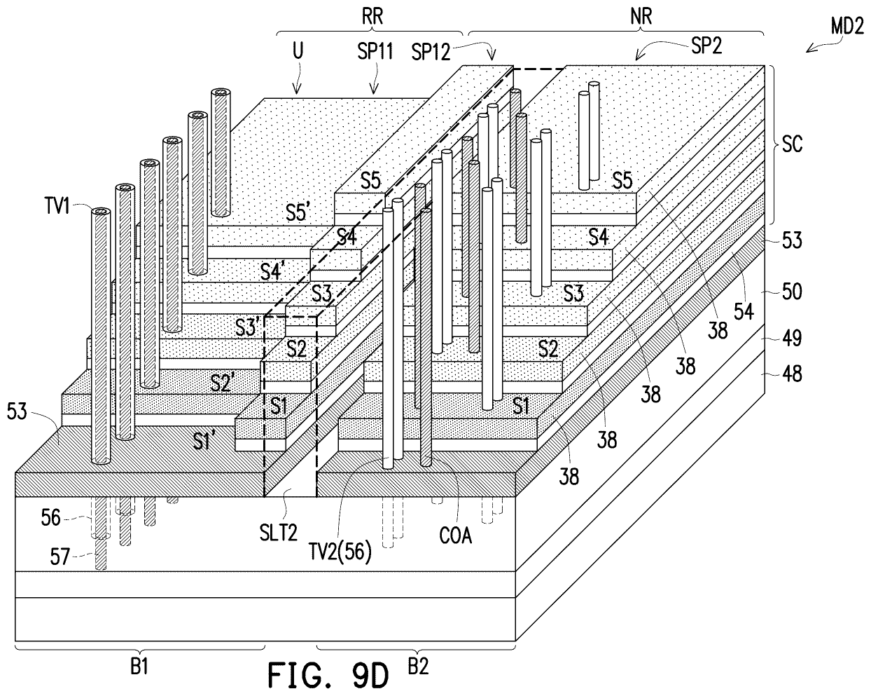

FIG. 8A to FIG. 8D are cross-sectional views of a method of fabricating the memory device of FIG. 4A. FIG. 9A to FIG. 9D are perspective views of a partial area 900 in FIG. 8A to FIG. 8D.

Referring to FIG. 8A to FIG. 8D and FIG. 9A to FIG. 9D, the fabricating method of the memory device MD2 in this embodiment is similar to the fabricating method of the memory device MD1 in FIG. 6A to FIG. 6E and FIG. 7A to FIG. 7E. In the above embodiments, the recess U has a flat bottom surface. In this embodiment, the bottom surface of the recess U is stepped. The method for forming the recess U in this embodiment includes forming a mask layer to expose a recess region RR. The mask layer may include a photoresist layer. Then, lithography and etching processes are performed to remove a part of the staircase structure SC to form the recess U. The etching process may include an anisotropic etching process. The mask layer is then removed. During the etching, the steps S5 to S1 of the recess region RR can be reduced by one step respectively through a time mode control, so as to form the stepped portion SP11 having the steps S5′ to S1′.

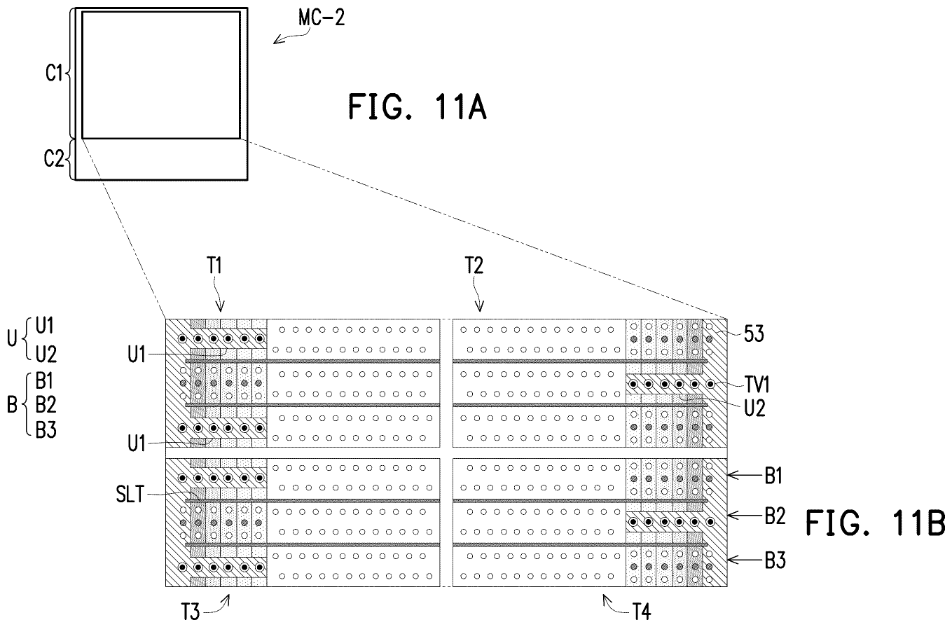

In addition to being used in 3D AND flash memory, the present disclosure can also be used in 3D NOR flash memory and 3D NAND flash memory. The structure of the 3D NOR flash memory can be shown in FIG. 2A and FIG. 2B. The die MC-2 of the 3D NAND flash memory can be shown in FIG. 11A and FIG. 11B.

In view of the above, in the embodiment of the present disclosure, all or part of the staircase structure for conductive vias is removed to form a recess, so as to reduce the number of layers of the staircase structure SC (especially the number of conductive layers) penetrated by the conductive vias. Therefore, the “open” issue that excessively inclined sidewall of the conductive via opening results in excessive insulating layer remaining at the bottom of the conductive via opening and therefore causes insufficient etching unable to reach the topmost conductive layer of the interconnection structure can be avoided. Therefore, the difficulty of the process can be reduced and the yield of the process can be improved by the method of the embodiment of the present disclosure.

Although the present disclosure has been disclosed above with the embodiments, it is not intended to limit the present disclosure. Anyone with ordinary knowledge in the technical field may make some changes and modifications without departing from the spirit and scope of the present disclosure. The scope of protection of the present disclosure should be defined by the scope of the appended patent application.

What is claimed is:

1. A memory device, comprising:
a substrate comprising a memory array region and a staircase region;
a stacked structure located on the substrate in the memory array region and the staircase region, wherein the stacked structure comprises a plurality of conductive layers and a plurality of insulating layers stacked alternately;
a separation wall extending through the stacked structure to divide the stacked structure into a first block and a second block;
a plurality of first through vias located in the first block of the staircase region;
a plurality of second through vias located in the second block of the staircase region and adjacent to the first through vias,
wherein a number of layers of the stacked structure penetrated by the first through vias is smaller than a number of layers of the stacked structure penetrated by the second through vias.

2. The memory device according to claim 1, wherein the first through vias are landed on and electrically connected to an interconnection structure on a substrate, and the second through vias are landed on and electrically isolated from the interconnection structure.

3. The memory device according to claim 1, further comprising a plurality of contacts located in the second block of the staircase region and landed on the conductive layers.

4. The memory device according to claim 1, wherein a diameter of the first through vias is greater than a diameter of the second through vias.

5. A memory device, comprising:
a substrate comprising a memory array region and a staircase region;
a memory array located in the memory array region;
a staircase structure located on the substrate in the staircase region, wherein the staircase structure comprises a recess region and a non-recess region, wherein a height of a top surface of the recess region is lower than a height of a top surface of the non-recess region; and
first through vias located in the recess region.

6. The memory device according to claim 5, wherein the recess region is located in a part of steps of the staircase structure.

7. The memory device according to claim 5, wherein the recess region is located in a high step, a middle step, a low step or a combination thereof of the staircase structure.

8. The memory device according to claim 5, wherein the recess region extends from a high step to a low step of the staircase structure.

9. The memory device according to claim 5, wherein the staircase structure comprises:
a first stepped portion located in the recess region; and
a second stepped portion located in the non-recess region, wherein a height of the first stepped portion is lower than a height of the second stepped portion, and a length of the first stepped portion is shorter than a length of the second stepped portion.

10. The memory device according to claim 9, wherein the first through vias extend through the first stepped portion; and
second through vias extend through the second stepped portion, wherein a diameter of the first through vias is greater than a diameter of the second through vias.

11. The memory device according to claim 10, further comprising:
contacts landed on the second stepped portion and adjacent to the second through vias.

12. The memory device according to claim 9, wherein the first through vias extend through the first stepped portion of the staircase structure; and
there is no through via extending through the second stepped portion.

13. The memory device according to claim 5, further comprising:
a separation wall extending through the staircase structure and dividing the staircase structure into a first block and a second block.

14. The memory device according to claim 13, wherein the recess region and the non-recess region are located in the first block.

15. The memory device according to claim 13, wherein the recess region is located in the first block, and the non-recess region is located in the second block.

16. The memory device according to claim 5, wherein the recess region comprises first recesses and second recesses staggered with each other, and respectively located at opposite sides of the memory array region of the substrate.

17. The memory device according to claim 5, wherein adjacent recesses of two adjacent tiles are staggered with each other.

18. A method of fabricating a memory device, comprising:
providing a substrate, the substrate comprising a memory array region and a staircase region;
forming a stacked structure in the memory array region and the staircase region;
patterning the stacked structure in the staircase region to form a staircase structure;
partially removing a part of the staircase structure to form a recess;
forming a memory array in the memory array region; and
forming first through vias in the recess.

19. The method according to claim 18, wherein partially removing the part of the staircase structure comprises:
partially removing a high step, a middle step, a low step or a combination thereof of the staircase structure.

20. The method according to claim 18, wherein the recess exposes a conductive layer below the staircase structure.
